(19) United States
(12) Patent Application Publication
(10) Pub. No.: US 2026/0324333 A1
(43) Pub. Date: Oct. 15, 2026

(54) METHOD FOR MANUFACTURING SEMICONDUCTOR DEVICE INCLUDING DICING WAFER

(71) Applicant: Samsung Electronics Co., Ltd., Suwon-si (KR)

(72) Inventors: Narae Han, Suwon-si (KR); Youngchul Kwon, Suwon-si (KR); Kyungsoon Park, Suwon-si (KR); Hyuckjun Yoo, Suwon-si (KR); Nam-Tae Heo, Suwon-si (KR)

(21) Appl. No.: 19/578,362

(22) Filed: Mar. 25, 2026

(30) Foreign Application Priority Data
Apr. 11, 2025 (KR) 10-2025-0047703

(51) Int. Cl. H10P 58/00; H10P 34/42

(52) U.S. Cl. CPC H10P 58/20; H10P 34/42

(57) ABSTRACT

A method for manufacturing a semiconductor device includes preparing a wafer having chip regions and scribe lane regions that define the chip regions, the scribe lane regions including a first scribe lane region and a second scribe lane region that extend parallel to each other in a scan direction, forming a first groove by emitting a first beam to the first scribe lane region along the scan direction, forming a second groove by emitting a second beam to the second scribe lane region along the scan direction, attaching a dicing tape to a backside of the wafer, and cutting the wafer into semiconductor devices. The first beam and the second beam are simultaneously emitted during a dual emission period. One of the first beam and the second beam is blocked during a single emission period, and the other one is emitted during the single emission period.

### CROSS-REFERENCE TO RELATED APPLICATION(S)

This application claims priority under 35 U.S.C. § 119 to Korean Patent Application No. 10-2025-0047703 filed on Apr.11, 2025, in the Korean Intellectual Property Office, the disclosure of which is incorporated by reference herein in its entirety.

### TECHNICAL FIELD

The present disclosure relates to a method for manufacturing a semiconductor device, and more particularly, relates to a method for cutting a wafer.

### BACKGROUND

A plurality of semiconductor chips are formed together on a semiconductor substrate, such as a wafer, and then separated from each other through a singulation process. In addition, in order to improve productivity with the rapid development of the electronics industry, a plurality of semiconductor packages, each of which includes a plurality of semiconductor chips, are also formed together on a semiconductor substrate, such as a wafer, or formed together by attaching them to a support substrate and then separated from each other through a singulation process.

As semiconductor devices become increasingly complex, the singulation of various semiconductor chips is essential. Accordingly, there is a need for a method capable of efficiently cutting a semiconductor substrate without causing defects.

### SUMMARY

Implementations of the present disclosure provide a semiconductor device manufacturing method with improved productivity.

Implementations of the present disclosure provide a semiconductor device manufacturing method with improved reliability and stability.

Implementations of the present disclosure provide a semiconductor device manufacturing method for efficiently cutting a wafer.

Implementations of the present disclosure provide a semiconductor device manufacturing method for simultaneously processing a plurality of scribe lane regions.

Implementations of the present disclosure provide a semiconductor device manufacturing method for individually controlling beams emitted to a plurality of scribe lane regions.

Implementations of the present disclosure provide a semiconductor device manufacturing method for preventing a beam for forming a groove on scribe lane regions from leaking out of a wafer.

According to some implementations, a method for manufacturing a semiconductor device includes preparing a wafer having chip regions and scribe lane regions that define the chip regions, the scribe lane regions including a first scribe lane region and a second scribe lane region that extend parallel to each other in a scan direction, forming a first groove by emitting a first beam to the first scribe lane region along the scan direction, forming a second groove by emitting a second beam to the second scribe lane region along the scan direction, attaching a dicing tape to a backside of the wafer, and cutting the wafer into semiconductor devices. The first beam and the second beam are simultaneously emitted during a dual emission period. One of the first beam and the second beam is blocked during a single emission period, and the other one of the first beam and the second beam is emitted during the single emission period.

According to some implementations, a method for manufacturing a semiconductor device includes preparing a wafer having chip regions and scribe lane regions that define the chip regions, the scribe lane regions including a first scribe lane region and a second scribe lane region that extend parallel to each other in a scan direction, and the second scribe lane region including a portion that faces the first scribe lane region and a second portion that does not face the first scribe lane region, dividing a laser beam into a first beam and a second beam, forming a first groove by emitting the first beam to the first scribe lane region along the scan direction, forming a second groove by emitting the second beam to the second scribe lane region along the scan direction, the first beam being blocked while the second beam is emitted to the second portion, attaching a dicing tape to a backside of the wafer, and forming semiconductor chips separate from each other by cutting the wafer.

According to some implementations, a method for manufacturing a semiconductor device includes preparing a wafer having chip regions and scribe lane regions that define the chip regions, the scribe lane regions including a first scribe lane region and a second scribe lane region that extend parallel to each other in a scan direction, dividing, by a spatial separation optical system, a laser beam into a first beam and a second beam, forming a first groove by emitting the first beam to the first scribe lane region along the scan direction, forming a second groove by emitting the second beam to the second scribe lane region along the scan direction, attaching a dicing tape to a backside of the wafer, and cutting the wafer into semiconductor devices. A distance between the first beam and the second beam in a direction perpendicular to the scan direction in a planar view is defined as a separation distance. The method further includes performing control such that the separation distance between the first beam and the second beam corresponds to a distance between the first scribe lane region and the second scribe lane region, by rotating the spatial separation optical system in the planar view before the emitting of the first beam and the emitting of the second beam.

### BRIEF DESCRIPTION OF THE DRAWINGS

The above and other objects and features of the present disclosure will become apparent by describing in detail implementations thereof with reference to the accompanying drawings.

FIG. 1A is a block diagram illustrating a laser cutting apparatus according to some implementations of the present disclosure.

FIG. 1B is a sectional block diagram taken along line Ⅰ-Ⅰ’ of FIG. 1A.

FIG. 2 is a block diagram illustrating an operating state of the laser cutting apparatus according to some implementations of the present disclosure.

FIG. 3 is a block diagram illustrating an operating state of the laser cutting apparatus according to some implementations of the present disclosure.

FIG. 4 is a conceptual diagram of a spatial separation optical system according to some implementations of the present disclosure.

FIG. 5 is a view illustrating an emission state of a first group of beams and a second group of beams depending on an operating state of the spatial separation optical system according to some implementations of the present disclosure.

FIG. 6 is a view illustrating an emission state of the first group of beams and the second group of beams depending on an operating state of the spatial separation optical system according to some implementations of the present disclosure.

FIG. 7 is a block diagram illustrating a laser cutting apparatus according to some implementations of the present disclosure.

FIG. 8 is a block diagram illustrating an operating state of the laser cutting apparatus according to some implementations of the present disclosure.

FIG. 9 is a flowchart illustrating a semiconductor device manufacturing method according to some implementations of the present disclosure.

FIG. 10 is a perspective view illustrating a part of the semiconductor device manufacturing method according to some implementations of the present disclosure.

FIGS. 11 and 12 are views for explaining a wafer including a base layer and a device layer according to some implementations of the present disclosure.

FIG. 13 is a perspective view illustrating a part of the semiconductor device manufacturing method according to some implementations of the present disclosure.

FIG. 14 is an enlarged plan view of a first region of FIG. 13.

FIG. 15 is a perspective view illustrating a part of the semiconductor device manufacturing method according to some implementations of the present disclosure.

FIG. 16 is an enlarged plan view of a second region of FIG. 15.

FIG. 17 is a perspective view illustrating a part of the semiconductor device manufacturing method according to some implementations of the present disclosure.

FIG. 18 is an enlarged plan view of a third region of FIG. 17.

FIG. 19 is a perspective view illustrating a part of the semiconductor device manufacturing method according to some implementations of the present disclosure.

FIG. 20 is an enlarged plan view of a fourth region of FIG. 19.

FIG. 21 is a perspective view illustrating a part of the semiconductor device manufacturing method according to some implementations of the present disclosure.

FIG. 22 is a perspective view illustrating a part of the semiconductor device manufacturing method according to some implementations of the present disclosure.

FIG. 23 is a perspective view illustrating a part of the semiconductor device manufacturing method according to some implementations of the present disclosure.

FIG. 24 is a flowchart illustrating a semiconductor device manufacturing method according to some implementations of the present disclosure.

FIG. 25 is a perspective view illustrating a part of the semiconductor device manufacturing method according to some implementations of the present disclosure.

FIG. 26 is an enlarged plan view of a fifth region of FIG. 25.

FIG. 27 is a sectional view of a semiconductor device according to some implementations of the present disclosure.

FIG. 28 is a sectional view specifically illustrating the semiconductor device of FIG. 27.

FIGS. 29 to 33 are sectional views illustrating a semiconductor device manufacturing method according to some implementations of the present disclosure.

FIG. 34 is a sectional view illustrating a semiconductor device manufactured by the semiconductor device manufacturing method according to some implementations of the present disclosure.

FIG. 35 is a view illustrating a semiconductor package according to some implementations of the present disclosure.

FIG. 36 is a view illustrating a semiconductor package according to some implementations of the present disclosure.

### DETAILED DESCRIPTION

Hereinafter, implementations of the present disclosure will be described clearly and in detail with reference to the accompanying drawings.

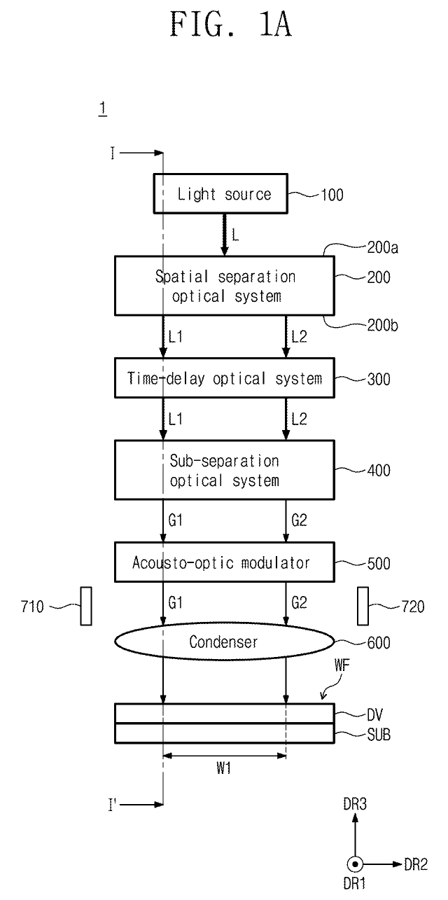

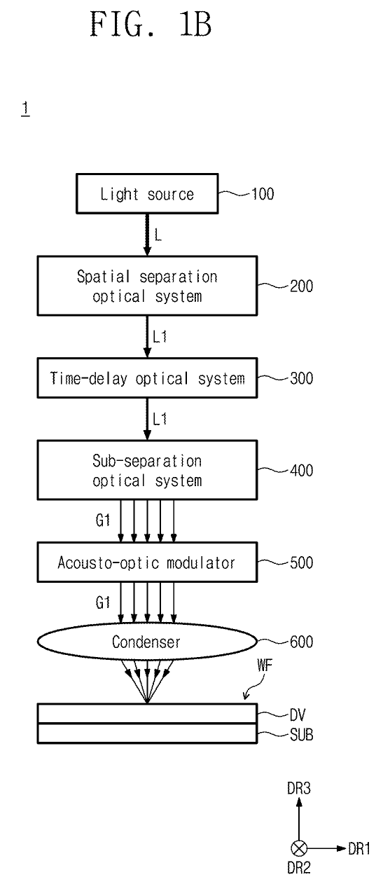

FIG. 1A is a block diagram illustrating a laser cutting apparatus 1 according to some implementations of the present disclosure. FIG. 1B is a sectional block diagram taken along line Ⅰ-Ⅰ’ of FIG. 1A.

Referring to FIGS. 1A and 1B, the laser cutting apparatus 1 may include at least one light source 100, a time-delay optical system 300, and an acousto-optic modulator 500.

The light source 100 may generate a laser beam L. The light source 100 may emit the laser beam L onto an object being processed while moving in a scan direction. For example, the light source 100 may emit a first beam L1 and/or a second beam L2 onto a wafer WF while moving in the scan direction.

The light source 100, which is a laser generator, may generate a femtosecond pulse laser beam L. The laser beam L may be a laser having a short pulse width of about 10⁻¹⁵ seconds. However, the type of laser beam L is not limited thereto, and the light source 100 may generate a picosecond pulse laser beam L.

The light source 100 may include a laser gain medium for generating the laser beam L and a nonlinear crystal medium for modulating the wavelength of the laser beam L. The laser gain medium may include a solid medium or a non-solid medium. The properties of the laser beam L may vary depending on the laser gain medium. For example, the laser gain medium may include a neodymium yttrium aluminum garnet compound (Nd:yAG), a neodymium yttrium orthovanadate compound (Nd:yVO4), an aluminum gallium arsenide compound (AlGaAS), an aluminum gallium indium compound (AlGaInP), a gallium nitride compound (GaN), a neodymium optical fiber (Nd-Fiber), or sapphire. In some implementations, the nonlinear crystal medium may include a KTiOPO₄ (KTP) crystal.

The laser beam L may be applied to a target point of the object being processed (e.g., the wafer WF) to form grooves GV by laser ablation. The focus generated by the laser beam L may be formed on a surface of the object being processed or at a point close to the surface. The focal spot of the laser beam L may be located at the target point (e.g., on a surface of the wafer WF, at a certain depth from the surface of the wafer WF, or above the surface of the wafer WF). The focal spot of the laser beam L may be scanned along one direction on the surface of the object being processed. The scan direction may correspond to a cut line for cutting the object being processed.

The laser beam L generated by the light source 100 may have a laser power in the range of about 1 W to about 100 W or about 10 W to about 70 W, a laser pulse duration in the range of about 100 fs to about 500 ps or about 500 fs to about 500ps, a laser pulse repetition rate in the range of about 10 kHz to about 2000 kHz, a nominal pulse energy in the range of about 50 μJ to about 300 μJ, a laser wavelength in the range of about 300 nm to about 1100 nm, and a laser scanning speed in the range of about 10 mm/s to about 3000 mm/s.

In some implementations, to minimize the occurrence of a heat affected zone, the laser beam L generated by the light source 100 may have the laser power in the range of about 0.1 W to about 30 W, the laser pulse duration in the range of about 500 fs to about 50 ps, the laser pulse repetition rate in the range of about 100 kHz to about 1000 kHz, the nominal pulse energy in the range of about 0.1 μJ to about 200 μJ, the laser wavelength in the range of about 330 nm to about 600 nm, and the laser scanning speed in the range of about 50 mm/s to about 2000mm/s.

The light source 100 may generate one or more laser beams L. In some implementations, the laser cutting apparatus 1 may include light sources that generate the laser beams L, respectively. For example, the light source 100 may include a first light source (not illustrated) configured to generate the first beam L1 and a second light source (not illustrated) configured to generate the second beam L2.

In some implementations, the laser cutting apparatus 1 may further include a spatial separation optical system 200 configured to spatially separate the laser beam L into the first beam L1 and the second beam L2. For example, the spatial separation optical system 200 may generate the first beam L1 and the second beam L2 using the laser beam L generated from the single light source 100. The spatial separation optical system 200 may spatially separate the first beam L1 and the second beam L2 in a direction crossing the scan direction.

The time-delay optical system 300 may separate the first beam L1 and the second beam L2 in time. The time-delay optical system 300 may change travel speeds depending on the polarization directions and optical axes of beams travelling through the inside thereof. For example, the time-delay optical system 300 may set different emission time points of the first beam L1 and the second beam L2 that are simultaneously incident on the time-delay optical system 300. The emission time point of the first beam, L1, may be delayed compared to the emission time point of the second beam, L2. In contrast, the emission time point of the second beam L2 may be delayed when compared to the emission time point of the first beam L1.

Specifically, the time-delay optical system 300 may include a birefringent material. The time-delay optical system 300 may include a uniaxial crystal having one optical axis. Based on the polarization directions of beams traveling through the inside of the time-delay optical system 300, the time-delay optical system 300 may provide different refractive indices for the respective beams. Accordingly, the travel speed of a beam perpendicular to the optical axis of the time-delay optical system 300 and the travel speed of a beam parallel to the optical axis of the time-delay optical system 300 may be different from each other within the uniaxial crystal. For example, the optical axis of the crystal in the time-delay optical system 300 and the optical axes of the first beam L1 and the second beam L2 that travel through the inside of the time-delay optical system 300 may form an angle of about 90 degrees. The travel speed of the first beam L1 polarized along the X-axis may be slower than the travel speed of the second beam L2 polarized along the Y-axis. Accordingly, even though the first beam L1 and the second beam L2 are simultaneously incident on the time-delay optical system 300, the emission time point of the first beam L1 may be later than the emission time point of the second beam L2.

Thus, a time delay may be generated between the first beam L1 and the second beam L2.

In addition, the time-delay optical system 300 may serve as a substantial phase delay plate for beams transmitted through the time-delay optical system 300.

The acousto-optic modulator (AOM) 500 may deflect beams in a specific direction using an acousto-optic effect. The acousto-optic modulator 500 may change the emission direction of a beam passing through the acousto-optic modulator 500 using the principle of diffraction of light. The acousto-optic modulator 500 may be referred to as an acousto-light modulator.

Specifically, the acousto-optic modulator 500 may include a piezoelectric element (not illustrated) that generates an induced diffraction grating and an RF power source (not illustrated) that applies a radio frequency (RF) voltage to the piezoelectric element. The acousto-optic modulator 500 may generate an induced diffraction grating in response to the RF voltage applied to the piezoelectric element, and the emission direction of a beam passing through the induced diffraction grating may be changed.

More specifically, the acousto-optic modulator 500 may periodically generate an induced diffraction grating. The RF power source may apply the RF voltage to the piezoelectric element, and the piezoelectric element may periodically generate an induced diffraction grating. The period of the RF voltage may correspond to the time delay generated between the first beam L1 and the second beam L2 by the time-delay optical system 300. For example, the acousto-optic modulator 500 may selectively change the emission direction of the first beam L1 or the second beam L2 by generating an induced diffraction grating in a period corresponding to the time delay between the first beam L1 and the second beam L2.

The laser cutting apparatus 1 may further include a light blocking device that absorbs the first beam L1 or the second beam L2, the emission direction of which is changed. For example, the laser cutting apparatus 1 may include a first light blocking device 710 for absorbing the first beam L1, the emission direction of which is changed by the acousto-optic modulator 500, and a second a light blocking device 720 for absorbing the second beam L2, the emission direction of which is changed by the acousto-optic modulator 500.

The laser cutting apparatus 1 may further include a sub-separation optical system 400. The sub-separation optical system 400 may spatially divide a beam into sub-beams in the scan direction. For example, the sub-separation optical system 400 may spatially divide the first beam L1 into first sub-beams G1 in the scan direction. In addition, the sub-separation optical system 400 may spatially divide the second beam L2 into second sub-beams G2 in the scan direction. The first beam L1 may include the first sub-beams G1, and the second beam L2 may include the second sub-beams G2. For example, when the scan direction of the laser beam L is referred to as a first direction DR1 and a direction perpendicular to the scan direction is referred to as a second direction DR2, the sub-separation optical system 40) may divide the first beam L1 and the second beam L2 into the first sub-beams G1 and the second sub-beams G2, respectively, in the first direction DR1. The first sub-beams G1 may be referred to as the first group of beams G1, and the second sub-beams G2 may be referred to as the second group of beams G2.

In FIG. 1B, the first beam L1 is illustrated as being divided into five first sub-beams G1 while passing through the sub-separation optical system 400. However, this is for the convenience of description, and the sub-separation optical system 400 may separate the first beam L1 or the second beam L2 into fewer or more sub-beams.

The sub-separation optical system 400 capable of dividing the first beam L1 or the second beam L2 into a plurality of sub-beams may include a beam splitter (e.g., a one-dimensional diffractive optical element (DOE)) and/or at least one optical lens.

The laser cutting apparatus 1 may further include a condenser 600 that collects sub-beams. For example, the condenser 600 may collect the first sub-beams G1 and/or the second sub-beams G2 and may emit the collected sub-beams onto the wafer WF. The collected sub-beams may form a single unit beam. For example, the collected first sub-beams G1 may form a first unit beam, and the collected second sub-beams G2 may form a second unit beam.

The laser cutting apparatus 1 may emit the first sub-beams G1 and/or the second sub-beams G2 onto the object being processed. For example, the object being processed may be the wafer WF. The wafer WF may include a base layer SUB and at least one device layer DV provided on the base layer SUB. The wafer WF may be cut to form semiconductor chips. That is, the semiconductor chips may be manufactured by cutting the wafer WF. The semiconductor chips may be referred to as semiconductor devices.

Although not illustrated, the laser cutting apparatus 1 may further include additional components in addition to the above-described components. For example, the laser cutting apparatus 1 may include at least one lens, at least one prism, at least one mirror, and a band pass filter that are capable of changing or controlling the path of light.

In addition, although not illustrated, the above-described components may be physically and/or electrically connected to a controller (not illustrated), and operations thereof may be controlled by the controller. In some implementations, the controller may be constituted by a computer. The controller may include a central processing unit (CPU) that performs operations depending on a control program, read-only memory (ROM) that stores the control program, random access memory (RAM) capable of writing and reading to temporarily store detected values and operation results, an input interface, and an output interface.

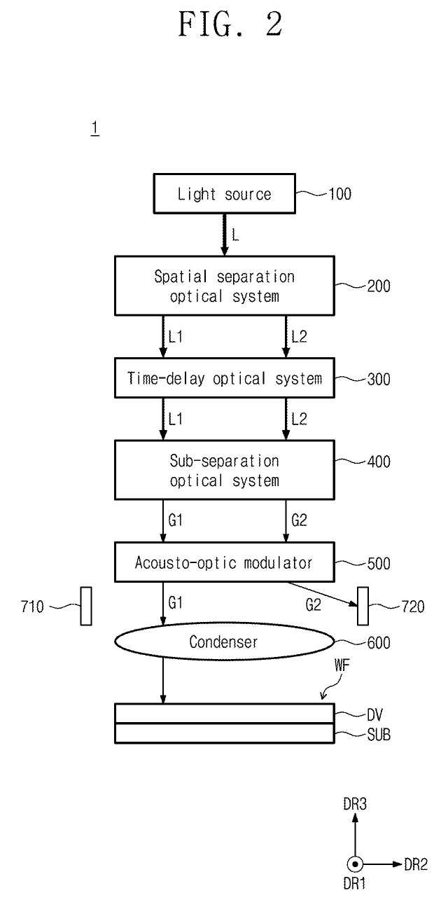

FIG. 2 is a block diagram illustrating an operating state of the laser cutting apparatus 1 according to some implementations of the present disclosure.

Referring to FIGS. 1A, 1B, and 2, the light source 100 may generate the laser beam L.

The spatial separation optical system 200 may spatially divide the laser beam L into the first beam L1 and the second beam L2 in the direction crossing the scan direction. Specifically, the spatial separation optical system 200 may spatially separate the laser beam L into the first beam L1 and the second beam L2, which have different polarization directions, in the second direction DR2. For example, the spatial separation optical system 200 may spatially divide the laser beam L into the first beam L1 polarized along the X-axis and the second beam L2 polarized along the Y-axis, in the second direction DR2.

The time-delay optical system 300 may transmit the first beam L1 and the second beam L2, but may generate a time delay between the first beam L1 and the second beam L2. For example, the emission time point of the first beam L1 may be later than the emission time point of the second beam L2.

The sub-separation optical system 400 may spatially divide the first beam L1 and the second beam L2 into the first sub-beams G1 and the second sub-beams G2, respectively, in the scan direction.

The acousto-optic modulator 500 may generate an induced diffraction grating in a period corresponding to the time delay between the first beam L1 and the second beam L2. For example, the acousto-optic modulator 500 may periodically generate the induced diffraction grating such that the emission direction of the second sub-beams G2 is changed, but the emission direction of the first sub-beams G1 is not changed. In this case, the second light blocking device 720 may absorb the second sub-beams G2, the emission direction of which is changed by the acousto-optic modulator 500. The condenser 600 may collect the first sub-beams G1 passing through the acousto-optic modulator 500 and may emit the collected first sub-beams G1 onto the wafer WF.

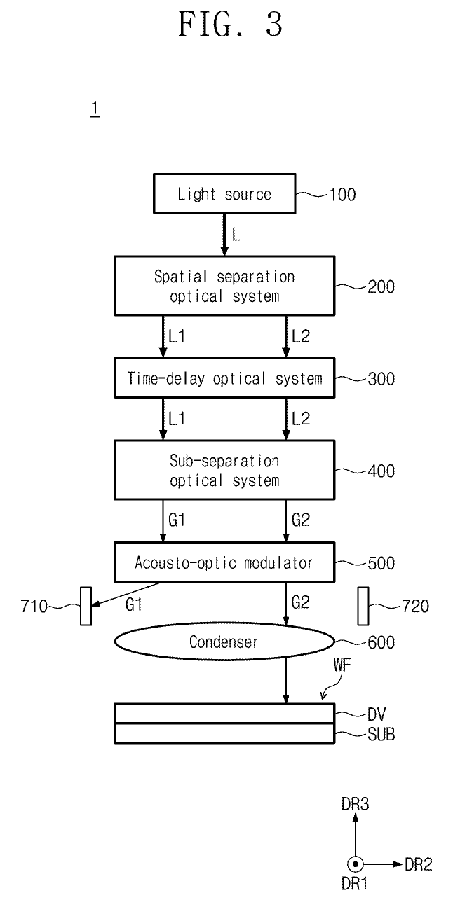

FIG. 3 is a block diagram illustrating an operating state of the laser cutting apparatus 1 according to some implementations of the present disclosure.

Referring to FIGS. 1A, 1B, and 3, the acousto-optic modulator 500 may periodically generate an induced diffraction grating such that the emission direction of the first sub-beams G1 is changed, but the emission direction of the second sub-beams G2 is not changed. In this case, the first light blocking device 710 may absorb the first sub-beams G1, the emission direction of which is changed by the acousto-optic modulator 500. The condenser 600 may collect the second sub-beams G2 passing through the acousto-optic modulator 500 and may emit the collected second sub-beams G2 onto the wafer WF.

FIGS. 2 and 3 illustrate an operating state in which the acousto-optic modulator 500 is turned on to change the emission direction of one of the first sub-beams G1 and the second sub-beams G2. However, without being limited thereto, as illustrated in FIG. 1, the acousto-optic modulator 500 may be turned off and may not change the emission directions of the first sub-beams G1 and the second sub-beams G2. In this case, the condenser 600 may collect the first sub-beams G1 and the second sub-beams G2 and may emit both the collected first sub-beams G1 and the collected second sub-beams G2 onto the wafer WF.

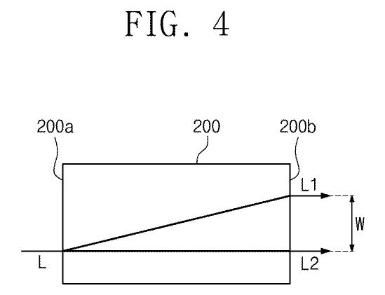

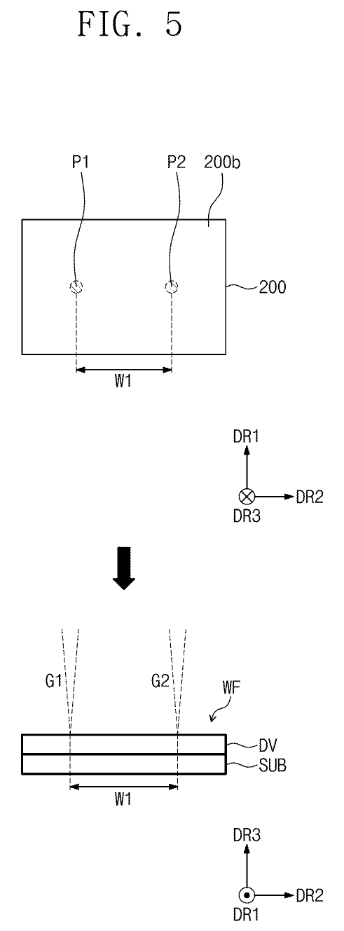

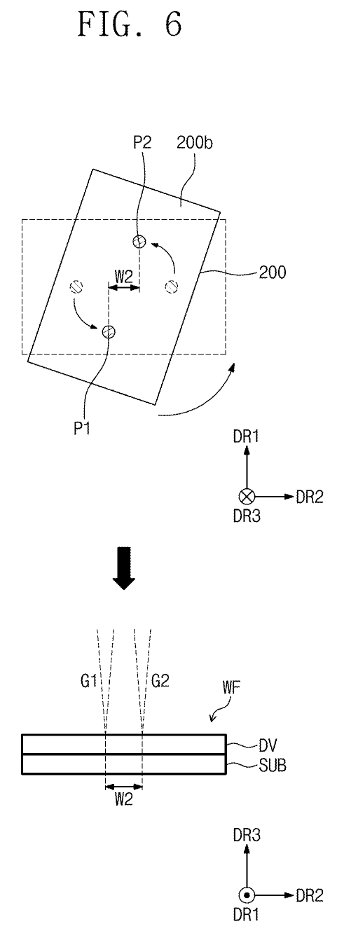

FIG. 4 is a conceptual diagram of the spatial separation optical system 200 according to some implementations of the present disclosure. FIG. 5 is a view illustrating an emission state of the first group of beams G1 and the second group of beams G2 depending on an operating state of the spatial separation optical system 200 according to some implementations of the present disclosure. FIG. 6 is a view illustrating an emission state of the first group of beams G1 and the second group of beams G2 depending on an operating state of the spatial separation optical system 200 according to some implementations of the present disclosure.

Referring to FIG. 4, the spatial separation optical system 200 may spatially divide the laser beam L into a plurality of beams. For example, the spatial separation optical system 200 may divide the laser beam L into the first beam L1 and the second beam L2 in a direction crossing the scan direction.

The spatial separation optical system 200 may include a light incident plane 200a to which the laser beam L is incident and a light exit plane 200b from which separated beams exit. In some implementations, the light incident plane 200a and the light exit plane 200b may be parallel to each other.

The beams that exit from the light exit plane 200b may be parallel to each other. For example, the first beam L1 and the second beam L2 that exit from the light exit plane 200b may be spaced apart from each other in the direction crossing the scan direction and may travel parallel to each other. The gap between the first beam L1 and the second beam L2 in the direction crossing the scan direction may correspond to (e.g., be substantially equal to) the length of one side of a semiconductor chip. For example, the gap between the first beam L1 and the second beam L2 in the direction crossing the scan direction may correspond to (e.g., be substantially equal to) the length of one side of a chip region CA. In some embodiments, each of the first beam L1 and the second beam L2 may have a diameter (or thickness). In this case, the gap between the first beam L1 and the second beam L2 may be defined as a distance between a center of the first beam L1 and a center of the second beam L2. The gap may be substantially equal to the length of one side of the semiconductor chip. In this disclosure, “substantially equal to” may be intended to allow for differences resulting from the removed regions. More specifically, in embodiments where removed regions are formed in scribe lane regions because of the first beam L1 and the second beam L2, the gap may be slightly larger than a length of one side of the semiconductor chip excluding the removed regions, in order to compensate for the length of the removed region. The difference may be substantially equal to the length of the removed region. In other words, the gap may be substantially equal to a length of one side of the semiconductor chip including the removed regions. Accordingly, the gap between the first beam L1 and the second beam L2 may still correspond to the length of one side of the semiconductor chip.

The spatial separation optical system 200 may include a birefringent material. The spatial separation optical system 200 may include a uniaxial crystal having one optical axis. Based on the polarization directions of beams traveling through the inside of the spatial separation optical system 200, the spatial separation optical system 200 may provide different refractive indices. For example, the optical axis of the crystal in the spatial separation optical system 200 and the optical axes of the first beam L1 and the second beam L2 that travel through the inside of the spatial separation optical system 200 may form an angle of about 30 degrees to about 60 degrees. The first beam L1 polarized along the X-axis may be refracted in the spatial separation optical system 200, and the second beam L2 polarized along the Y-axis may not be refracted in the spatial separation optical system 200 or may be refracted less than the first beam L1.

Accordingly, the first beam L1 and the second beam L2 may be spatially separate from each other.

Referring to FIGS. 4 and 5, the laser beam L passing through the spatial separation optical system 200 may be spatially divided into the first beam L1 and the second beam L2. Thereafter, the first beam L1 and the second beam L2 may be spatially divided into the first sub-beams G1 and the second sub-beams G2, respectively, in the scan direction while passing through the sub-separation optical system 400, and the first sub-beams G1 and the second sub-beams G2 may be spaced apart from each other by a first separation distance W1 in the direction crossing the scan direction. The distance between the first beam L1 and the second beam L2 in a direction perpendicular to the scan direction in a planar view or the distance between the first sub-beams G1 and the second sub-beams G2 in the direction perpendicular to the scan direction in the planar view may be defined as a separation distance W. In some embodiments, each of the first beam L1 and the second beam L2 may have a diameter (or thickness). The separation distance W may be defined as a distance between the center of the first beam L1 and the center of the second beam L2.

The light exit plane 200b of the spatial separation optical system 200 may include a first light exit point P1 from which the first beam L1 exits and a second light exit point P2 from which the second beam L2 exits. The gap between the first light exit point P1 and the second light exit point P2 may correspond to (e.g., be functionally related to) the separation distance W between the first sub-beams G1 and the second sub-beams G2. In some embodiments, the gap between the first light exit point P1 and the second light exit point P2 may be proportional to the separation distance W between the first beam L1 and the second beam L2.

Referring to FIGS. 4 to 6, the spatial separation optical system 200 may rotate in a planar view to adjust the separation distance W between the first beam L1 and the second beam L2 in the direction perpendicular to the scan direction. Specifically, the spatial separation optical system 200 may rotate counterclockwise in a planar view, and the separation distance W between the first sub-beams G1 and the second sub-beams G2 in the direction perpendicular to the scan direction may be reduced to a second separation distance W2 smaller than the first separation distance W1. More specifically, as the spatial separation optical system 200 rotates counterclockwise by about 90 degrees in a planar view, the separation distance W between the first sub-beams G1 and the second sub-beams G2 in the direction perpendicular to the scan direction may be gradually reduced. As the spatial separation optical system 200 rotated by about 90 degrees is further rotated by about 180 degrees in the counterclockwise direction, the separation distance W between the first sub-beams G1 and the second sub-beams G2 in the direction perpendicular to the scan direction may be gradually increased.

The decrease or increase in the separation distance W between the first sub-beams G1 and the second sub-beams G2 in the direction perpendicular to the scan direction may be based on a decrease or increase in the gap between the first light exit point P1 and the second light exit point P2 in the second direction DR2.

Accordingly, corresponding to (e.g., being substantially equal to) the length of one side of each semiconductor chip, the laser cutting apparatus 1 may control the separation distance W between the first beam L1 and the second beam L2 in the direction perpendicular to the scan direction or the separation distance W between the first sub-beams G1 and the second sub-beams G2 in the direction perpendicular to the scan direction.

In addition, corresponding to (e.g., being substantially equal to) the distance between a pair of scribe lane regions SA adjacent to each other, the laser cutting apparatus 1 may control the separation distance W between the first beam L1 and the second beam L2 in the direction perpendicular to the scan direction or the separation distance W between the first sub-beams G1 and the second sub-beams G2 in the direction perpendicular to the scan direction. In some embodiments, the distance between the pair of scribe lane regions may be defined as a distance between a center of one scribe lane region and a center of the other scribe lane region.

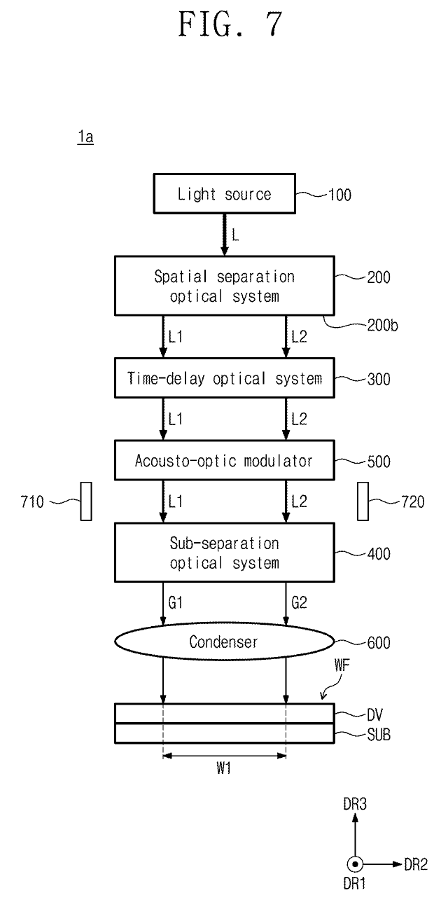

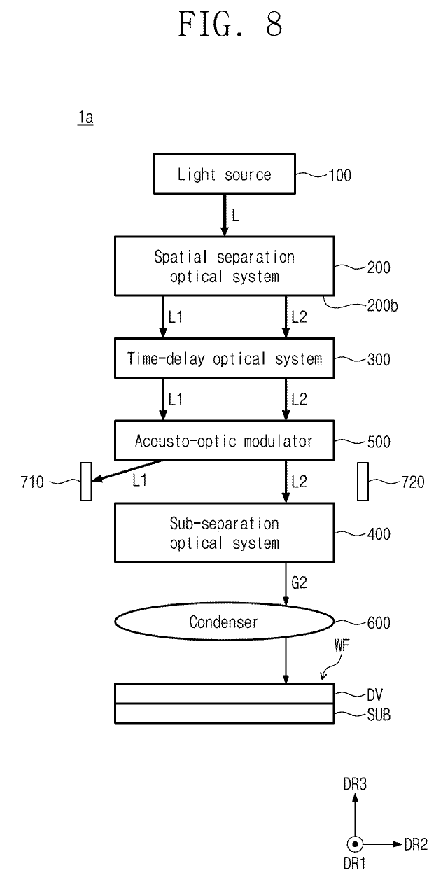

FIG. 7 is a block diagram illustrating a laser cutting apparatus 1a according to some implementations of the present disclosure. FIG. 8 is a block diagram illustrating an operating state of the laser cutting apparatus 1a according to some implementations of the present disclosure.

Referring to FIGS. 7 and 8, an acousto-optic modulator 500 may be provided between a time-delay optical system 300 and a sub-separation optical system 400. The acousto-optic modulator 500 may change the emission direction of a first beam L1 or a second beam L2 passing through the time-delay optical system 300. For example, the acousto-optic modulator 500 may change the emission direction of the first beam L1 passing through the time-delay optical system 300, but may not change the emission direction of the second beam L2 passing through the time-delay optical system 300. A first light blocking device 710 may absorb the first beam L1, the emission direction of which is changed. The sub-separation optical system 400 may spatially divide the second beam L2, the emission direction of which is not changed, into second sub-beams G2 in a scan direction. A condenser 600 may collect the second sub-beams G2 and may emit the collected second sub-beams G2 onto an object being processed.

In contrast, the acousto-optic modulator 500 may change the emission direction of the second beam L2 passing through the time-delay optical system 300, but may not change the emission direction of the first beam L1 passing through the time-delay optical system 300. A second light blocking device 720 may absorb the second beam L2, the emission direction of which is changed. The sub-separation optical system 400 may spatially divide the first beam L1, the emission direction of which is not changed, into first sub-beams G1 in the scan direction. The condenser 600 may collect the first sub-beams G1 and may emit the collected first sub-beams G1 onto the object being processed.

Alternatively, the acousto-optic modulator 500 may pass the first beam L1 and the second beam L2 without changing the emission direction of the first beam L1 and the emission direction of the second beam L2. The sub-separation optical system 400 may spatially divide the first beam L1 and the second beam L2 into the first sub-beams G1 and the second sub-beams G2, respectively, in the scan direction. The condenser 600 may collect the first sub-beams G1 and the second sub-beams G2 and may emit the collected first sub-beams G1 and the collected second sub-beams G2 onto the object being processed.

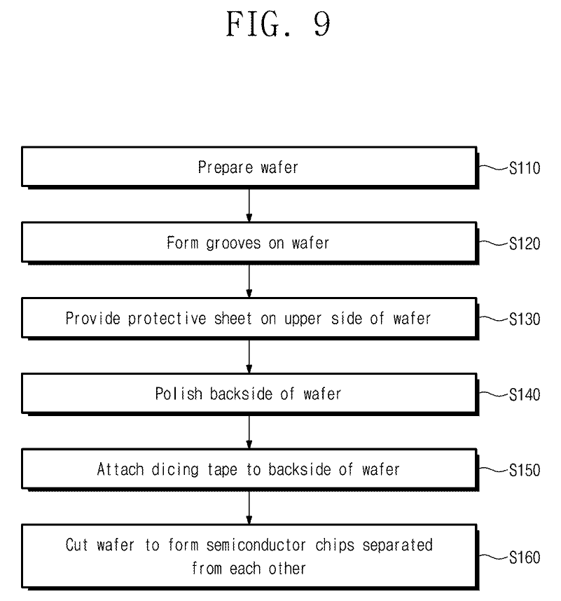

FIG. 9 is a flowchart illustrating a semiconductor device manufacturing method according to some implementations of the present disclosure.

Referring to FIG. 9, according to some implementations of the present disclosure, the semiconductor device manufacturing method (hereinafter, the “manufacturing method”) may include preparing a wafer (S110), forming a groove on the wafer (S120), attaching a dicing tape to the backside of the wafer (S150), and forming semiconductor chips separate from each other by cutting the wafer (S160).

The manufacturing method may further include providing a protective sheet on the upper side of the wafer (S130). The providing of the protective sheet on the upper side of the wafer (S130) may be performed before the attaching of the dicing tape to the backside of the wafer (S150).

The manufacturing method may further include polishing the backside of the wafer (S140). The polishing of the backside of the wafer (S140) may be performed between the preparing of the wafer (S110) and the attaching of the dicing tape to the backside of the wafer (S150). The polishing of the backside of the wafer (S140) may be performed after the providing of the protective sheet on the upper side of the wafer (S130).

The forming of the groove on the wafer (S120) may be performed after the preparing of the wafer (S110) and before the attaching of the dicing tape to the backside of the wafer (S150).

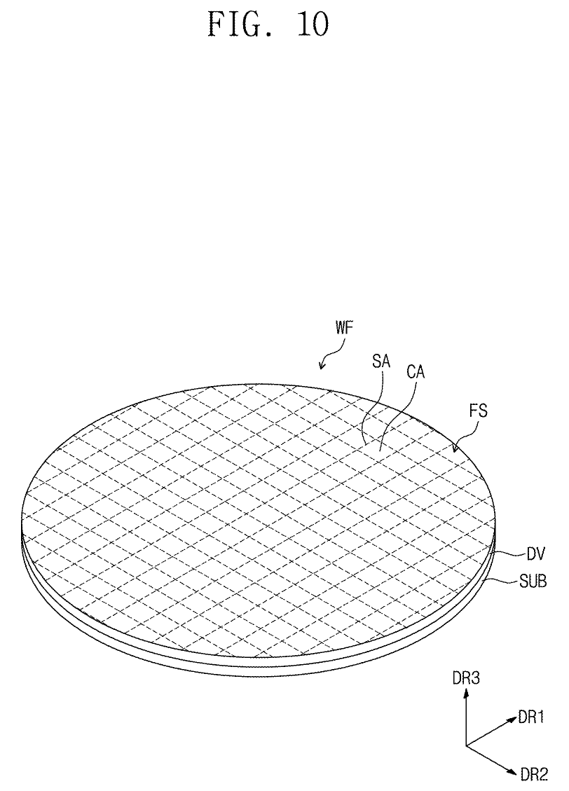

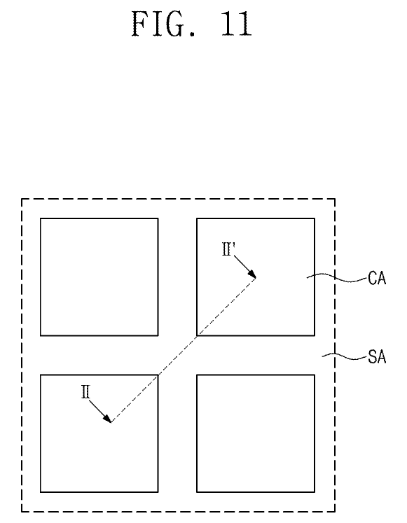

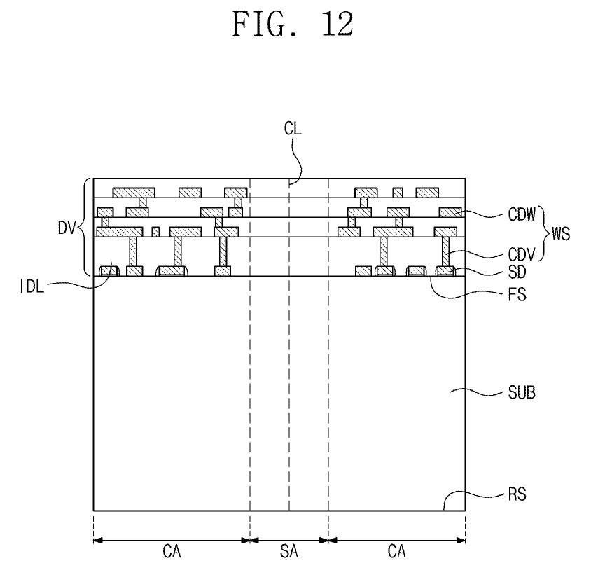

FIG. 10 is a perspective view illustrating a part of the semiconductor device manufacturing method according to some implementations of the present disclosure. FIGS. 11 and 12 are views for explaining the wafer WF including the base layer SUB and the device layer DV according to some implementations of the present disclosure.

Referring to FIGS. 9 and 10 to 12, the wafer WF may be prepared. The wafer WF may include the base layer SUB and at least one device layer DV provided on the base layer SUB. The device layer DV may be provided on the frontside FS of the base layer SUB. In FIG. 10, for convenience of description, the device layer DV is illustrated as a single layer. However, the device layer DV may include various components.

The wafer WF may include chip regions CA and scribe lane regions SA. The scribe lane regions SA may define the chip regions CA. The scribe lane regions SA may extend parallel to each other in the scan direction. For example, the scribe lane regions SA may extend in the first direction DR1 and the second direction DR2 and may cross each other at a right angle. Accordingly, the chip regions CA may be defined between the scribe lane regions SA crossing each other. Here, the chip regions CA and the scribe lane regions SA may extend to the base layer SUB and the device layer DV in a direction perpendicular to the frontside FS and may be used as terms for distinguishing the regions of the wafer WF.

The base layer SUB may be a circular wafer having a constant thickness. In some implementations, the base layer SUB may mean a substrate that is formed of or includes a semiconductor material and/or a substrate that is used as a base to form a semiconductor device even though it does not include a semiconductor material. In some implementations, the base layer SUB may be a silicon wafer. However, without being limited thereto, the base layer SUB may be a wafer including a semiconductor element such as germanium or a compound such as silicon carbide (SiC), gallium arsenide (GaAs), indium arsenide (InAs), or indium phosphide (InP). Alternatively, the base layer SUB may have a silicon on insulator (SOI) structure. In some implementations, the base layer SUB may include an impurity-doped well or an impurity-doped structure that is a conductive region. In addition, the base layer SUB may have various device isolation structures such as a shallow trench isolation (STI) structure.

The device layer DV having a plurality of integrated circuit regions may be formed on the frontside FS of the base layer SUB. In a subsequent process, the chip regions CA may be separate from each other together with the base layer SUB and may be provided as semiconductor chips.

The plurality of chip regions CA may include a plurality of devices SD. The devices SD may be classified into a memory device and a logic device.

The memory device may constitute a volatile memory device or a non-volatile memory device. For example, the volatile memory device may include a memory device such as dynamic random access memory (DRAM), static RAM (SRAM), thyristor RAM (TRAM), zero-capacitor RAM (ZRAM), or twin-transistor RAM (TTRAM). In addition, the non-volatile memory device may include, for example, a memory device such as flash memory, magnetic RAM (MRAM), spin-transfer torque MRAM (STT-MRAM), ferroelectric RAM (FRAM), phase change RAM (PRAM), resistive RAM (RRAM), nanotube RRAM, polymer RAM, nano floating gate memory, holographic memory, molecular electronics memory, or insulator resistance change memory.

The logic device may be implemented as, for example, a microprocessor, a graphics processor, a signal processor, a network processor, an audio codec, a video codec, an application processor, or a system on a chip (SOC), but is not limited thereto.

The chip regions CA may be isolated from each other by the scribe lane regions SA. The plurality of scribe lane regions SA may include a region through which a cut line passes. Here, the cut line may be a virtual line. In a dicing process to be described below, the wafer WF may be cut along the cut line. Portions extending in a row direction and portions extending in a column direction may intersect each other to form the scribe lane regions SA. Each of the scribe lane regions SA may be in the form of a straight lane having a constant width. As illustrated in FIG. 10, the chip regions CA may be arranged in rows and columns with the scribe lane regions SA therebetween. The chip regions CA may be surrounded by the scribe lane regions SA and may be spaced apart from each other.

The chip regions CA may be regions in which the devices SD for memory or logic functions are formed. The scribe lane regions SA may be regions in which the devices SD are not formed. In some implementations, a plurality of dummy devices may be arranged in the scribe lane regions SA.

The device layer DV may include an interlayer dielectric layer IDL that is disposed on the frontside FS and that covers the devices SD and a wiring structure WS disposed on the interlayer dielectric layer IDL and connected to the devices SD. The wiring structure WS may have a multilayer wiring structure WS in which an insulating layer and conductive wiring CDW are alternately arranged. In addition, the conductive wiring CDW of each layer may include a plurality of conductive vias CDV disposed in the direction perpendicular to the frontside FS of the base layer SUB. For example, the conductive wiring CDW and the conductive vias CDV may be formed of a conductive material including at least one of aluminum (Al), copper (Cu), nickel (Ni), tungsten(W), platinum (Pt), or gold (Au).

The interlayer dielectric layer IDL may be formed of a low-k material. The low-k material may be a material having a lower dielectric constant than silicon oxide, and when used as the interlayer dielectric layer IDL in the semiconductor device, the low-k material may be advantageous in implementing high integration and high speed of the semiconductor device due to an improved insulating ability. A dummy structure similar to the wiring structure WS may be formed in the scribe lane regions SA. For example, the dummy structure disposed in the scribe lane regions SA may include multilayer dummy wirings corresponding to the respective conductive wirings CDW together with the interlayer dielectric layer IDL and the insulating layers. In some implementations, the scribe lane regions SA may include test patterns for testing the semiconductor devices SD in the chip regions CA or a redistribution layer for connection between the test patterns or may include an alignment key for alignment of a mask. In addition, in some implementations, a material layer having various functions, such as a passivation layer, may be additionally formed on the device layer DV.

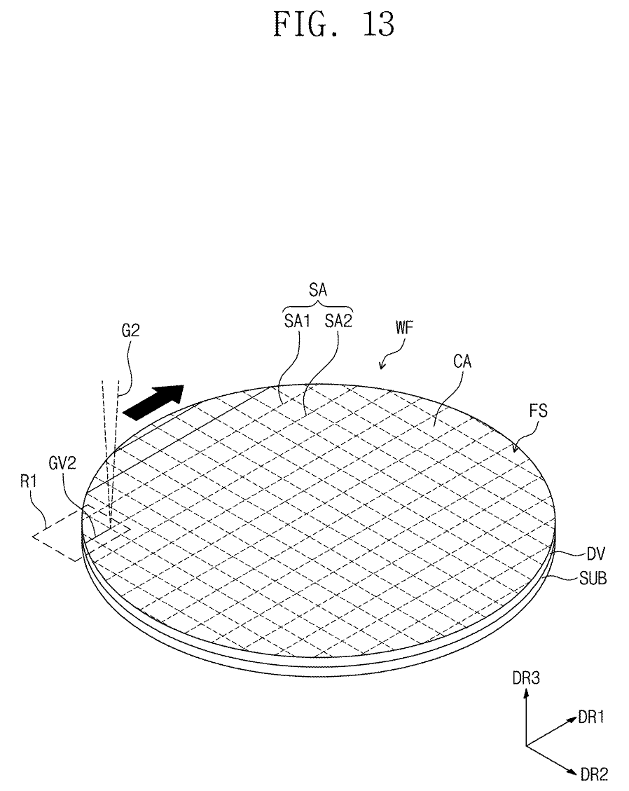

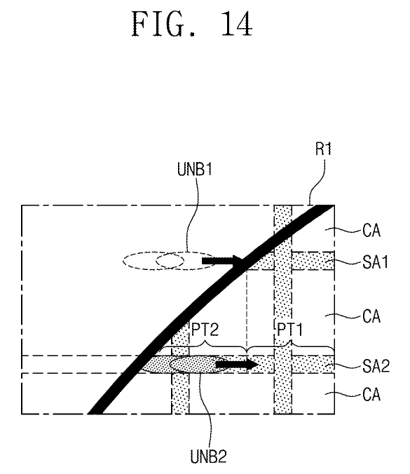

FIG. 13 is a perspective view illustrating a part of the semiconductor device manufacturing method according to some implementations of the present disclosure. FIG. 14 is an enlarged plan view of a first region R1 of FIG. 13.

Referring to FIGS. 9 and 13, the forming of the grooves GV on the wafer WF (S120) may be performed. The forming of the grooves GV on the wafer WF (S120) may be referred to as a dicing step. The dicing step may be a step of removing only a portion of the wafer WF and may be referred to as a half-dicing step.

In the process of forming the grooves GV on the wafer WF, the above-described laser cutting apparatus 1 may emit a laser beam onto the wafer WF. However, the present disclosure is not limited thereto, and a laser cutting apparatus 1 rather than the above-described laser cutting apparatus 1 may emit a laser beam onto the wafer WF without departing from the spirit and scope of the present disclosure. For convenience of description, only a portion of the laser cutting apparatus 1 is illustrated in the drawing.

The laser cutting apparatus 1 may emit the laser beam L in a direction from the upper side to the lower side of the wafer WF. The laser beam L may be emitted through a laser emitting device that is connected to the main body of the laser cutting apparatus 1 and that emits the laser beam L.

The laser beam L emitted by the laser cutting apparatus 1 may be selected from light having the following characteristics. In some implementations, the laser beam L may have a wavelength band of about 100 nm to about 600 nm. In some implementations, the laser beam L may have a pulse width of about 1 fs to about 1000 ns, for example, about 1 fs to about 20 ps. In some implementations, the laser beam L may have an energy per pulse of about 0.1 μJ to about 50 μJ. In some implementations, the accumulated energy per unit area of the laser beam L may range from about 0.1 J/m² to about 1000 J/m². The laser beam L may have a width of about 1 μm to about 1000 μm.

The laser emitting device may move along the cut line in the scribe lane regions SA of the wafer WF. For example, the laser emitting device may move in horizontal directions (e.g., in directions parallel to the frontside FS of the wafer WF and perpendicular to each other) such that the laser beam L is emitted along the scribe lane regions SA. In contrast, a stage having the wafer WF mounted thereon may be moved with the laser emitting device fixed, such that the laser beam L is emitted to the scribe lane regions SA. Alternatively, the stage having the wafer WF mounted thereon and the laser emitting device may be simultaneously moved such that the laser beam L is emitted to the scribe lane regions SA.

The corresponding region of the wafer WF may be removed by the laser beam L emitted onto the wafer WF, and thus the grooves GV may be formed. The grooves GV may be formed through at least a portion of the wafer WF. The grooves GV may penetrate at least a portion of the device layer DV and may penetrate a portion of the base layer SUB provided under the device layer DV.

The grooves GV may act as crack sites where cracks occur due to external physical impact.

Specifically, the scribe lane regions SA may include a first scribe lane region SA1 and a second scribe lane region SA2. The first scribe lane region SA1 and the second scribe lane region SA2 may be parallel to each other.

The first scribe lane region SA1 and the second scribe lane region SA2 may have different lengths. For example, the length of the second scribe lane region SA2 may be greater than the length of the first scribe lane region SA1.

The forming of the grooves GV on the wafer WF may include forming a first groove GV1 by emitting the first beam L1 to the first scribe lane region SA1 along the scan direction and forming a second groove GV2 by emitting the second beam L2 to the second scribe lane region SA2 along the scan direction.

The emitting of the first beam L1 and the emitting of the second beam L2 may be independently performed. The emitting of the first beam L1 and the emitting of the second beam L2 may be selectively performed. For example, only one of the emitting of the first beam L1 and the emitting of the second beam L2 may be performed, and the other one of the emitting of the first beam L1 and the emitting of the second beam L2 may be stopped. The stopping of the other one of the emitting of the first beam L1 and the emitting of the second beam L2 may be implemented by blocking the other one of the emitting of the first beam L1 and the emitting of the second beam L2.

The emitting of the first beam L1 and the emitting of the second beam L2 may be simultaneously performed.

Accordingly, the plurality of scribe lane regions SA may be simultaneously processed, and thus the semiconductor device manufacturing method with improved productivity may be provided.

In addition, the semiconductor device manufacturing method capable of efficiently cutting the wafer WF may be provided.

A time period, during which only one of the first beam L1 and the second beam L2 is emitted and the other one of the first beam L1 and the second beam L2 is not emitted, may be referred to as a single emission period. That is, during the single emission period, only one of the emitting of the first beam L1 and the emitting of the second beam L2 may be performed.

A time period during which the emitting of the first beam L1 and the emitting of the second beam L2 are simultaneously performed may be referred to as a dual emission period.

The forming of the grooves GV on the wafer WF (S120) may include at least one single emission period and at least one dual emission period. Specifically, the forming of the first groove GV1 and the second groove GV2 in the first scribe lane region SA1 and the second scribe lane region SA2, respectively, may include a single emission period and a dual emission period. The single emission period may precede the dual emission period. The single emission period may follow the dual emission period. Alternatively, the dual emission period may be provided between a pair of single emission periods.

The forming of the first groove GV1 and the second groove GV2 in the first scribe lane region SA1 and the second scribe lane region SA2 that have different lengths will be described. The length of the second scribe lane region SA2 may be greater than the length of the first scribe lane region SA1. Specifically, the second scribe lane region SA2 may include a first portion PT1 that faces the first scribe lane region SA1 and at least one second portion PT2 that does not face the first scribe lane region SA1.

FIGS. 13 and 14 are views illustrating a process of forming the second groove GV2 by emitting the second beam L2 to one of the second portions PT2 of the second scribe lane region SA2. Since the length of the second scribe lane region SA2 is greater than the length of the first scribe lane region SA1, the emitting of the second beam L2 to the second scribe lane region SA2 may precede the emitting of the first beam L1 to the first scribe lane region SA1. For example, during the single emission period, the second groove GV2 may be formed in one of the second portions PT2 of the second scribe lane region SA2.

When the second beam L2 is emitted to one of the second portions PT2 of the second scribe lane region SA2 during the single emission period, the emitting of the first beam L1 may be stopped. The stopping of emitting the first beam L1 may include blocking the emitting of the first beam L1. For example, the emission direction of the first beam L1 may be changed by the acousto-optic modulator 500, and the first beam L1, the emission direction of which is changed, may be absorbed by the first light blocking device 710. As a result, the emitting of the second beam L2 may start before the emitting of the first beam L1.

Accordingly, the first beam L1 may not be emitted to a region outside the wafer WF, and thus a phenomenon in which the first beam L1 is scattered in a chamber may be minimized.

In addition, the semiconductor device manufacturing method with improved reliability and stability may be provided.

However, the present disclosure is not limited thereto, and in some implementations, even though the length of the second scribe lane region SA2 is greater than the length of the first scribe lane region SA1, the emitting of the second beam L2 may simultaneously start with the emitting of the first beam L1 or may start after the emitting of the first beam L1. This is because the spatial precedence relationship between the first light exit point P1 and the second light exit point P2 varies as the above-described spatial separation optical system 200 rotates in a planar view.

The manufacturing method may further include spatially dividing the laser beam L into the first beam L1 and the second beam L2 before the emitting of the first beam L1 and the emitting of the second beam L2. For example, the laser beam L generated by the single light source 100 may be spatially divided into the first beam L1 and the second beam L2 in the direction crossing the scan direction by the spatial separation optical system 200. Accordingly, a plurality of beams may be generated from the single light source 100.

The manufacturing method may further include providing the first beam L1 and the second beam L2 to the time-delay optical system 300 before the emitting of the first beam L1 and the emitting of the second beam L2. The time-delay optical system 300 may make the emission time point of one of the first beam L1 and the second beam L2 later than the emission time point of the other one of the first beam L1 and the second beam L2. For example, the time-delay optical system 300 may make the emission time point of the first beam L1 later than the emission time point of the second beam L2.

The manufacturing method may further include providing the first beam L1 and the second beam L2 into the acousto-optic modulator 500 before the emitting of the first beam L1 and the emitting of the second beam L2. The providing of the first beam L1 and the second beam L2 into the acousto-optic modulator 500 may be performed after the providing of the first beam L1 and the second beam L2 to the time-delay optical system 300. For example, the first beam L1 and the second beam L2, passing through the time-delay optical system 300, may be provided to the acousto-optic modulator 500.

The acousto-optic modulator 500 may change the emission direction of the first beam L1 or the emission direction of the second beam L2 by using the difference between the emission time points of the first beam L1 and the second beam L2. For example, during the single emission period in which the second beam L2 is emitted to one of the second portions PT2 of the second scribe lane region SA2, the acousto-optic modulator 500 may change the emission direction of the first beam L1 by using the difference between the emission time points of the first beam L1 and the second beam L2.

The first beam L1, the emission direction of which is changed, may not be emitted to the first scribe lane region SA1. The emission direction of the first beam L1 may be changed by the acousto-optic modulator 500 such that the first beam L1 departs from the wafer WF. The first beam L1, the emission direction of which is changed, may be absorbed by the first light blocking device 710.

The acousto-optic modulator 500 may not change the emission direction of the second beam L2. The second beam L2, the emission direction of which is not changed, may be emitted to the second scribe lane region SA2. However, without being limited thereto, the acousto-optic modulator 500 may slightly change the emission direction of the second beam L2 within the range in which the second beam L2 is emitted to the second scribe lane region SA2.

Here, the emitting of the first beam L1 may include emitting the first sub-beams G1 spatially separate from each other in the scan direction. In addition, the emitting of the second beam L2 may include emitting the second sub-beams G2 spatially separate from each other in the scan direction. The first sub-beams G1 may be referred to as the first group of beams G1, and the second sub-beams G2 may be referred to as the second group of beams G2.

The second sub-beams G2 may form a second unit beam UNB2. A unit beam may refer to beams that are emitted in the same time period as a single output. The second unit beams UNB2 that are sequentially emitted may overlap in the second scribe lane region SA2. For example, the laser cutting apparatus 1 may form the second groove GV2 in one of the second portions PT2 by sequentially providing the second unit beams UNB2 to one of the second portions PT2 of the second scribe lane region SA2 while moving in the scan direction. However, without being limited thereto, the laser cutting apparatus 1 may cut one of the second portions PT2 of the second scribe lane region SA2 by sequentially providing the second unit beams UNB2 while moving in the scan direction.

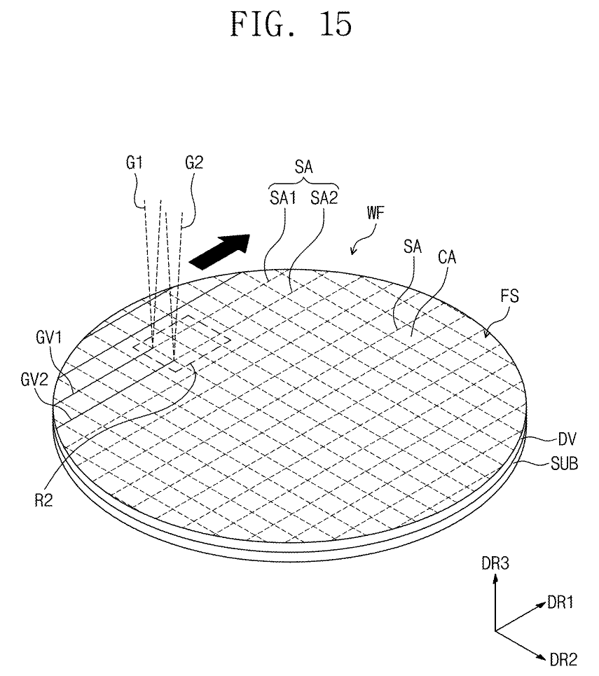

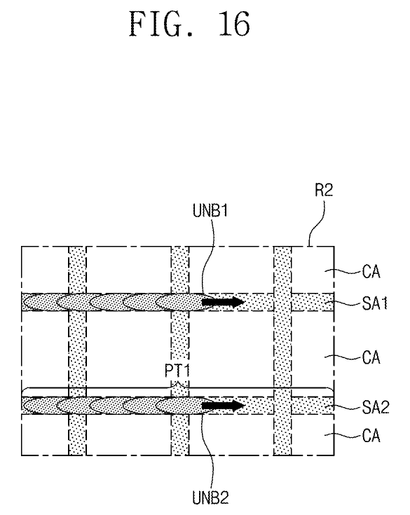

FIG. 15 is a perspective view illustrating a part of the semiconductor device manufacturing method according to some implementations of the present disclosure. FIG. 16 is an enlarged plan view of a second region R2 of FIG. 15.

Referring to FIGS. 9, 15, and 16, the dual emission period for forming the grooves GV on the wafer WF may be performed. Specifically, emitting the first beam L1 to the first scribe lane region SA1 and emitting the second beam L2 to the second scribe lane region SA2 may be simultaneously performed. For example, during the dual emission period, the first beam L1 may be emitted to the first scribe lane region SA1, and the second beam L2 may be emitted to a first portion PT1 of the second scribe lane region SA2. The emitting of the first beam L1 and the emitting of the second beam L2 may be simultaneously performed in the scan direction.

After the second beam L2 is emitted to one of second portions PT2 of the second scribe lane region SA2 during the single emission period, the emitting of the first beam L1 to the first scribe lane region SA1 and the emitting of the second beam L2 to the first portion PT1 of the second scribe lane region SA2 may start at the same time.

In addition, the emitting of the first beam L1 to the first scribe lane region SA1 and the emitting of the second beam L2 to the first portion PT1 of the second scribe lane region SA2 may end at the same time.

Specifically, first unit beams UNB1 that are sequentially emitted may overlap in the first scribe lane region SA1. The first sub-beams G1 may form the first unit beam UNB1. For example, the laser cutting apparatus 1 may form the first groove GV1 in the first scribe lane region SA1 by sequentially providing the first unit beams UNB1 while moving in the scan direction. However, without being limited thereto, the laser cutting apparatus 1 may cut the first scribe lane region SA1 by sequentially providing the first unit beams UNB1 while moving in the scan direction.

In addition, the second unit beams UNB2 that are sequentially emitted may overlap in the second scribe lane region SA2. For example, the laser cutting apparatus 1 may form the second groove GV2 in the first portion PT1 of the second scribe lane region SA2 by sequentially providing the second unit beams UNB2 while moving in the scan direction. However, without being limited thereto, the laser cutting apparatus 1 may cut the first portion PT1 of the second scribe lane region SA2 by sequentially providing the second unit beams UNB2 while moving in the scan direction.

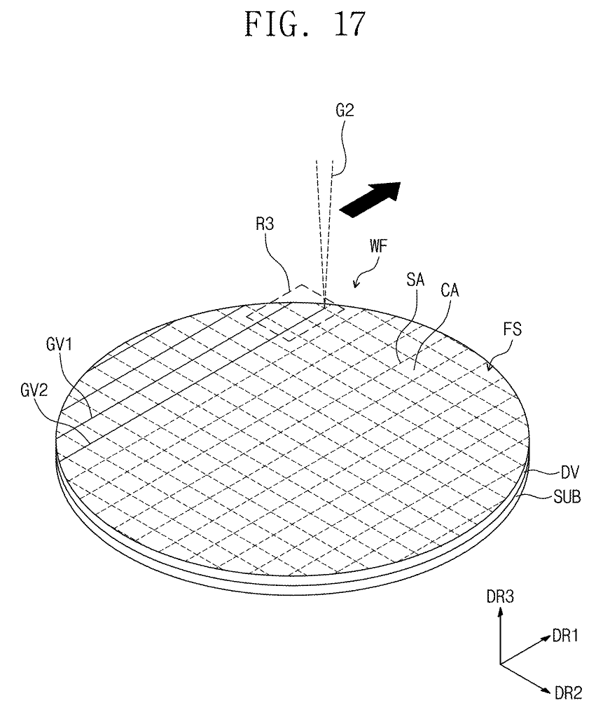

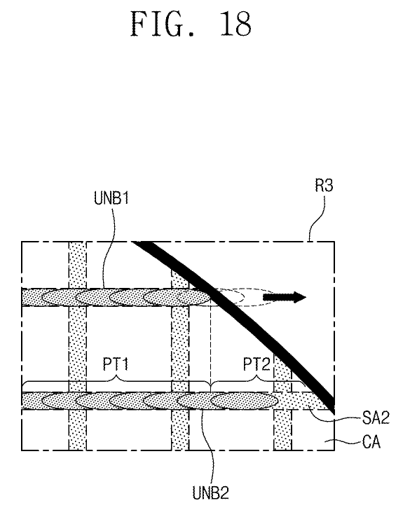

FIG. 17 is a perspective view illustrating a part of the semiconductor device manufacturing method according to some implementations of the present disclosure. FIG. 18 is an enlarged plan view of a third region R3 of FIG. 17.

A process of forming the second groove GV2 by emitting the second beam L2 to another one of the second portions PT2 of the second scribe lane region SA2 will be described with reference to FIGS. 9, 17 and 18, . Since the length of the second scribe lane region SA2 is greater than the length of the first scribe lane region SA1, the single emission period may follow the dual emission period. For example, the emitting of the second beam L2 to the other one of the second portions PT2 of the second scribe lane region SA2 may follow emitting the first beam L1 to the first scribe lane region SA1 and emitting the second beam L2 to the first portion PT1 of the second scribe lane region SA2.

When the second beam L2 is emitted to the other one of the second portions PT2 of the second scribe lane region SA2 during the single emission period, the emitting of the first beam L1 may be stopped. The stopping of emitting the first beam L1 may include blocking the emitting of the first beam L1. For example, the emission direction of the first beam L1 may be changed by the acousto-optic modulator 500, and the first beam L1, the emission direction of which is changed, may be absorbed by the first light blocking device 710. As a result, the emitting of the second beam L2 may end after the emitting of the first beam L1.

Accordingly, the first beam L1 may not be emitted to a region outside the wafer WF, and thus a phenomenon in which the first beam L1 is scattered in the chamber may be minimized.

In addition, the semiconductor device manufacturing method with improved reliability and stability may be provided.

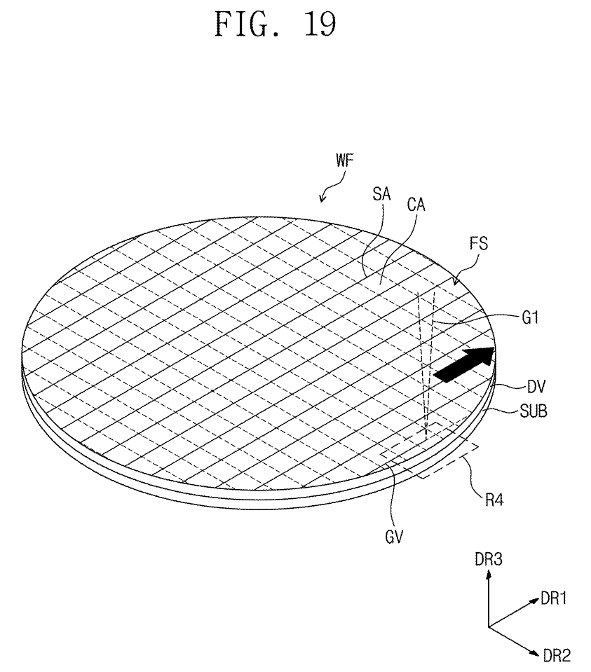

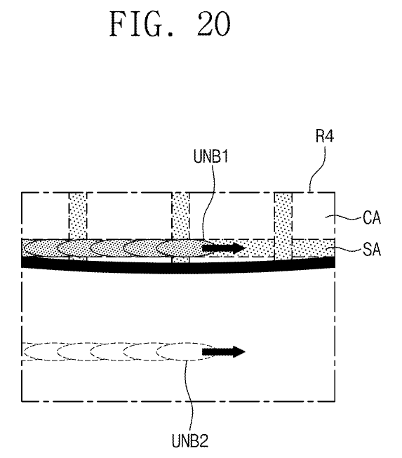

FIG. 19 is a perspective view illustrating a part of the semiconductor device manufacturing method according to some implementations of the present disclosure. FIG. 20 is an enlarged plan view of a fourth region R4 of FIG. 19.

Referring to FIGS. 9, 19 and 20, the number of scribe lane regions SA may be odd. For example, the scribe lane regions SA may include the first scribe lane region SA1, the second scribe lane region SA2, and an odd number of scribe lane regions SA. Accordingly, the total number of scribe lane regions SA may be odd.

The scribe lane regions SA may include at least one pair of scribe lane regions SA and one remaining scribe lane region SA. For example, the odd number of scribe lane regions SA includes at least one pair of scribe lane regions and one remaining scribe lane region.

The first beam L1 and the second beam L2 may be emitted to the one pair of scribe lane regions SA. Specifically, while grooves GV are formed in each of the one pair of scribe lane regions SA, the first beam L1 and/or the second beam L2 may be emitted through the single emission period and the dual emission period.

One of the first beam L1 and the second beam L2 may be emitted to the one remaining scribe lane region SA. One of the first beam L1 and the second beam L2 may be emitted to the one remaining scribe lane region SA, and the other one of the first beam L1 and the second beam L2 may be stopped. Forming a groove GV in the one remaining scribe lane region SA may include the single emission period. The forming of the groove GV in the one remaining scribe lane region SA may not include the dual emission period. For example, only emitting the first beam L1 to the one remaining scribe lane region SA may be performed, and emitting the second beam L2 may be stopped.

Specifically, the first unit beams UNB1 that are sequentially emitted may overlap in the one remaining scribe lane region SA. For example, the laser cutting apparatus 1 may form the groove GV in the one remaining scribe lane region SA by sequentially providing the first unit beams UNB1 to the one remaining scribe lane region SA while moving in the scan direction. However, without being limited thereto, the laser cutting apparatus 1 may cut the one remaining scribe lane region SA by sequentially providing the first unit beams UNB1 while moving in the scan direction.

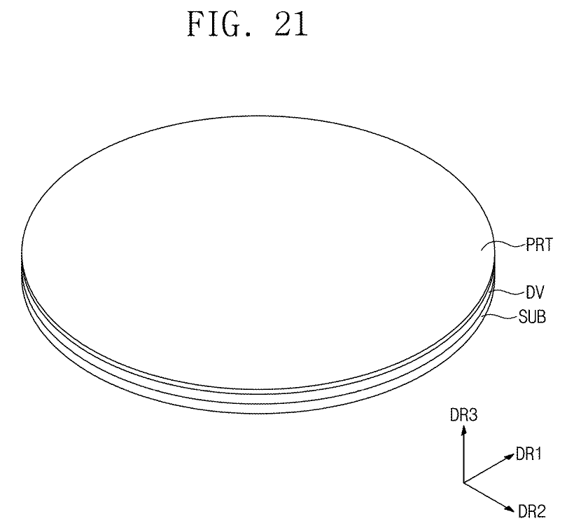

FIG. 21 is a perspective view illustrating a part of the semiconductor device manufacturing method according to some implementations of the present disclosure.

Referring to FIGS. 9 and 21, the protective sheet PRT may be provided on the frontside FS of the wafer WF. The protective sheet PRT serves to prevent the surface of the wafer WF from being damaged in a subsequent process. For example, the protective sheet PRT may prevent foreign matter from being attached to the upper side of the device layer DV.

Although not illustrated, the protective sheet PRT may include a polymer resin. The type of polymer resin is not particularly limited. In some implementations, the protective sheet PRT may be formed by forming a film of a thermosetting resin or curing the thermosetting resin or may be formed by forming a film of a thermoplastic resin. The protective sheet PRT may be formed of a resin capable of ensuring adhesion to the wafer WF, prevention of penetration of foreign matter, and washability after cutting of the semiconductor wafer WF. For example, the protective sheet PRT may include a fat-soluble resin or a water-soluble resin. The protective sheet PRT may be formed to have various thicknesses as needed.

In some implementations, the fat-soluble resin may include a polyurethane resin including a urea group that is polymerized by reacting with alcohol or amine isocyanate, or a thermoplastic resin such as polystyrene (PS), polyethylene terephthalate (PET), or polypropylene (PP). The thermoplastic resin may have a molecular weight of about 1000 Mw to about 1,000,000 Mw. The water-soluble resin may include polyvinyl alcohol (PVA), polyvinyl pyrrolidone (PVP), or an ionic polymer having an ionic functional group.

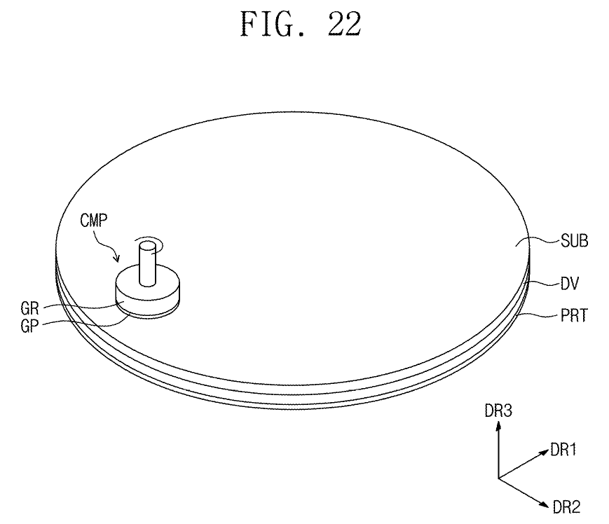

FIG. 22 is a perspective view illustrating a part of the semiconductor device manufacturing method according to some implementations of the present disclosure.

Referring to FIGS. 9 and 22, the backside RS of the wafer WF may be polished. The polishing of the backside RS of the wafer WF may be performed by using a polishing apparatus CMP.

The wafer WF having the protective sheet PRT attached to the upper side thereof may be inverted such that the backside RS of the wafer WF faces upward and may be placed on a chuck table (not illustrated). The backside RS of the wafer WF may be a side on which the device layer DV is not formed and may correspond to an inactive side.

The thickness of the base layer SUB in the wafer WF may be reduced by polishing the backside RF of the wafer WF.

The polishing apparatus CMP may include the chuck table that supports the base layer SUB and a grinder GR that polishes the base layer SUB disposed on the chuck table. The grinder GR may move while rotating, and a polishing pad GP may be attached to the bottom of the grinder GR.

The polishing process may be a grinding process in a state in which physical pressure is applied to the base layer SUB. The polished base layer SUB may have a smaller thickness after being polished than before being polished.

In some implementations, a crack generated from the groove GV may be easily propagated through the process of polishing the backside RS of the wafer WF. In some implementations, at least some of the cracks generated from the grooves GV may be propagated toward the backside RS of the base layer SUB in the polishing process. However, the propagation of the cracks generated from the grooves GV may not occur in the step of polishing the wafer WF, but may occur in a step of expanding the dicing tape TP to be described below.

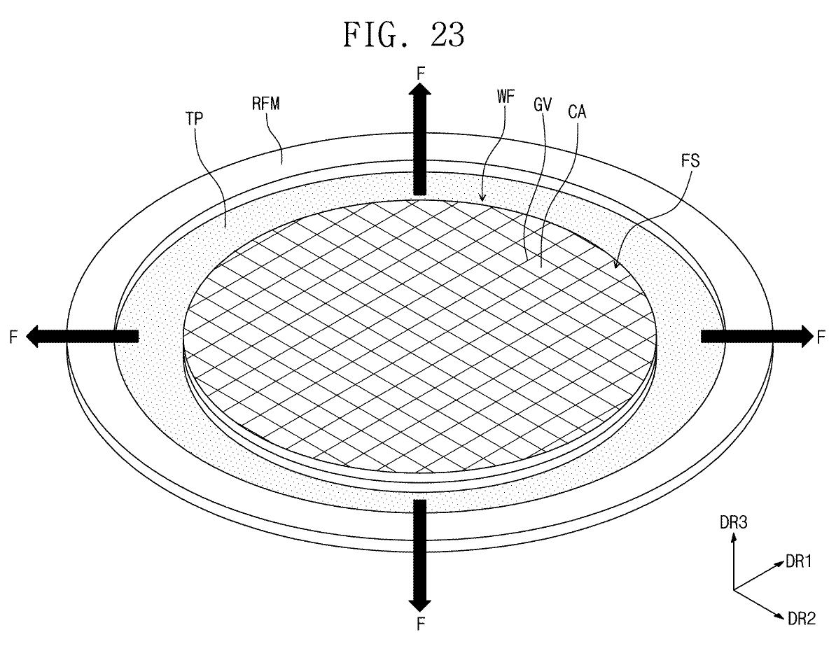

FIG. 23 is a perspective view illustrating a part of the semiconductor device manufacturing method according to some implementations of the present disclosure.

Referring to FIGS. 9 and 23, the wafer WF may be attached to the dicing tape TP.

The wafer WF may be inverted again, such that the upper side to which the protective sheet PRT is provided faces upward and may be attached to the dicing tape TP. In some implementations, the backside RF of the wafer WF may be attached to the dicing tape TP.

Although not separately illustrated, an adhesive film may be attached to the backside RS of the wafer WF. The adhesive film may serve to support the wafer WF and may facilitate handling of the wafer WF later. The adhesive film may be provided on the backside RS of the wafer WF before the wafer WF is attached to the dicing tape TP. In this case, the wafer WF may be attached to the dicing tape TP with the adhesive film therebetween. Alternatively, the adhesive film may be attached to the backside RS of the wafer WF before the grooves GV are formed on the wafer WF.

The protective sheet PRT may be removed after the wafer WF is attached to the dicing tape TP. The protective sheet PRT may be delaminated by a film delamination apparatus or may be removed by a wet cleaning process. The wet cleaning process may be performed using an organic solvent or an inorganic solvent, depending on the material of the protective sheet PRT.

The dicing tape TP may be supported and fixed by a ring frame RFM attached to one side thereof.

Thereafter, an external force F may be applied to the dicing tape TP to expand the dicing tape TP such that the semiconductor chips are separate from the wafer WF. The dicing tape TP may be radially expanded as illustrated.

In some implementations, the dicing tape TP may be placed on a jig and may be expanded by pushing the jig upward.

By expanding the dicing tape TP, the wafer WF may be cut into the individual semiconductor chips along the scribe lane regions SA. When the dicing tape TP is expanded while the wafer WF is disposed on the dicing tape TP, the base layer SUB may be subject to brittle fracture. The brittle fracture refers to the destruction of an object without permanent deformation when a force exceeding an elastic limit is applied to the object. The base layer SUB may be subject to brittle fracture due to cracks propagating from the region where the grooves GV are formed. The cracks generated from the grooves GV may propagate toward the backside RS of the base layer SUB as the dicing film is expanded. As the cracks are formed along the scribe lane regions SA that isolate the chip regions CA from each other, the chip regions CA may be divided into the semiconductor chips by the brittle fracture of the base layer SUB.

Although not illustrated, each of the semiconductor chips may be picked up and transmitted to a separate support substrate by a different process apparatus. The support substrate may be a temporary carrier that supports and fixes the semiconductor chips before a die attach process is performed.

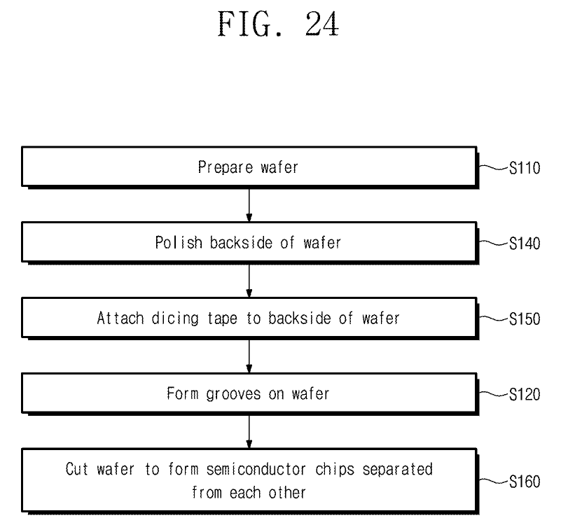

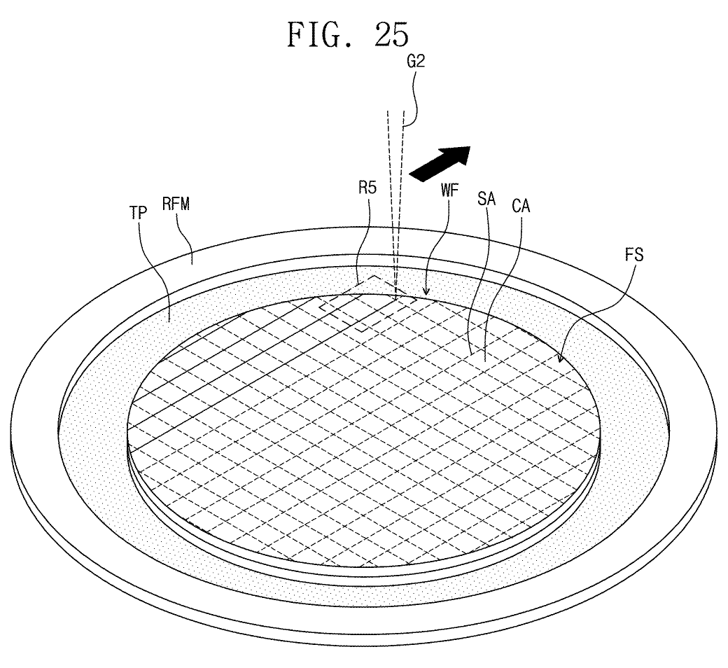

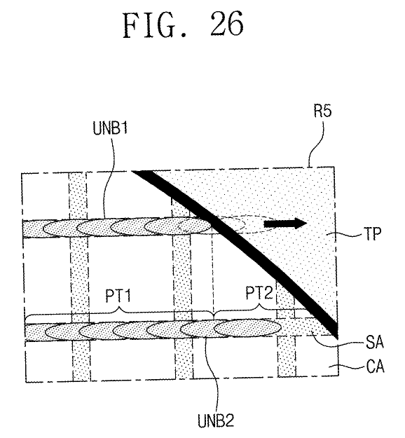

FIG. 24 is a flowchart illustrating a semiconductor device manufacturing method according to some implementations of the present disclosure. FIG. 25 is a perspective view illustrating a part of the semiconductor device manufacturing method according to some implementations of the present disclosure. FIG. 26 is an enlarged plan view of a fifth region R5 of FIG. 25.

According to some implementations of the present disclosure, the process of manufacturing the semiconductor chips by cutting the wafer WF may be performed in a sequence different from the above-described sequence.

Referring to FIG. 24, the forming of the grooves on the wafer (S120) may be performed after the attaching of the dicing tape to the backside of the wafer (S150). For example, the forming of the grooves by emitting the first beam and/or the second beam to the wafer (S120) may be performed in the state in which the dicing tape is attached to the backside of the wafer.

A process of forming the second groove GV2 by emitting the second beam L2 to another one of the second portions PT2 of the second scribe lane region SA2 will be described with reference to FIGS. 24 to 26. Since the length of the second scribe lane region SA2 is greater than the length of the first scribe lane region SA1, the single emission period may follow the dual emission period. For example, the emitting of the second beam L2 to the other one of the second portions PT2 of the second scribe lane region SA2 may follow the emitting of the first beam L1 to the first scribe lane region SA1 and the emitting of the second beam L2 to the first portion PT1 of the second scribe lane region SA2.

When the second beam L2 is emitted to the other one of the second portions PT2 of the second scribe lane region SA2 during the single emission period, the emitting of the first beam L1 may be stopped. The stopping of emitting the first beam L1 may include blocking the emitting of the first beam L1. For example, the emission direction of the first beam L1 may be changed by the acousto-optic modulator 500, and the first beam L1, the emission direction of which is changed, may be absorbed by the first light blocking device 710. As a result, the emitting of the second beam L2 may end after the emitting of the first beam L1.

Accordingly, the first beam L1 may not be emitted to a region outside the wafer WF, and thus a phenomenon in which the first beam L1 is emitted to the dicing tape TP may be minimized. Thus, by-products generated when the laser beam L is emitted to the dicing tape TP may be minimized.

In addition, the semiconductor device manufacturing method with improved reliability and stability may be provided.

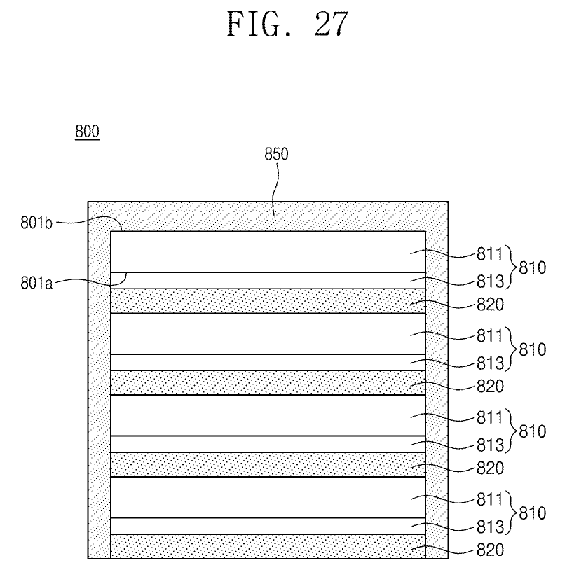

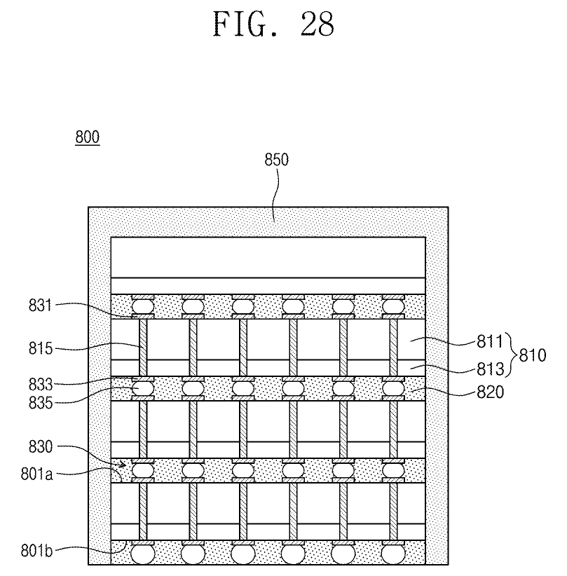

FIG. 27 is a sectional view illustrating a semiconductor device according to some implementations of the present disclosure. FIG. 28 is a sectional view specifically illustrating the semiconductor device of FIG. 27.

Referring to FIGS. 27 and 28, the semiconductor device 800 according to some implementations of the present disclosure may include a plurality of semiconductor chips 810, for example, four semiconductor chips 810. The plurality of semiconductor chips 810 may be sequentially stacked with adhesive layers 820 therebetween.

The semiconductor chips 810 may be logic chips and/or memory chips. For example, the plurality of semiconductor chips 810 may all be memory chips of the same type. Alternatively, some of the plurality of semiconductor chips 810 may be memory chips, and the others may be logic chips. Each of the memory chips may be, for example, a volatile memory chip, such as dynamic random access memory (DRAM) or static random access memory (SRAM), or a non-volatile memory chip, such as phase-change random access memory (PRAM), magnetoresistive random access memory (MRAM), ferroelectric random access memory (FeRAM), or resistive random access memory (RRAM). In some implementations of the present disclosure, the semiconductor chips 810 may be high bandwidth memory (HBM) DRAM. In addition, each of the logic chips may be, for example, a microprocessor, an analog device, or a digital signal processor.

Meanwhile, although FIGS. 27 and 28 illustrate the semiconductor device 800 in which the four semiconductor chips 810 are stacked, the number of semiconductor chips 810 stacked in the semiconductor device 800 is not limited thereto. For example, two, three, or five or more semiconductor chips 810 may be stacked in the semiconductor device 800.

Each of the semiconductor chips 810 may include a chip substrate 811 and a device layer 813 provided on the chip substrate 811.

The chip substrate 811 may have a frontside 801a and a backside 801b. The frontside 801a and the backside 801b may be opposite each other. The frontside 801a may be a side of the chip substrate 811 on which the device layer 813 is formed, and the backside 801b may be a side opposite to the frontside 801a. The frontside 801a may be an active side on which a plurality of integrated circuits are formed, and the backside 801b may be an inactive side.

The chip substrate 811 may be, for example, a doped or undoped silicon substrate. In some implementations, the chip substrate 811 may include other semiconductor materials such as germanium, a compound semiconductor including silicon carbide, gallium arsenide, gallium phosphide, indium phosphide, an indium arsenide compound, and/or an indium antimony compound, a hybrid semiconductor including SiGe, GaAsP, AlInAs, AlGaAs, GaInAs, GaInP and/or GaInAsP, or a combination thereof. The chip substrate 811 may be formed of a single layer or multiple layers. In some implementations, the chip substrate 811 may have a silicon on insulator (SOI) structure. For example, the chip substrate 811 may include a BOx layer (a buried oxide layer). The chip substrate 811 may include a conductive region, for example, an impurity-doped well or an impurity-doped structure. In addition, the chip substrate 811 may have various device isolation structures, such as a shallow trench isolation (STI) structure.

The device layer 813 may be provided on the frontside 801a of the chip substrate 811. The device layer 813 may include a plurality of individual devices and/or wires connecting the individual devices.

Each of the semiconductor chips 810 may further include a through-via 815, a first pad 831, and a second pad 833. The through-via 815 may penetrate the chip substrate 811 and may extend from the frontside 801a toward the backside 801b of the chip substrate 811 or from the backside 801b toward the frontside 801a of the chip substrate 811. The through-via 815 may be connected to wires (not illustrated) that are provided in the device layer 813. Alternatively, the through-via 815 may penetrate the device layer 813 and may be connected to the first pad 831 and/or the second pad 833. The through-via 815, the first pad 831, and/or the second pad 833 may be directly connected as illustrated, but may be electrically connected via various other wires (not illustrated).

In each of the semiconductor chips 810, the first pad 831 may be disposed on the device layer 813. The first pad 831 may be electrically connected with a wiring structure (not illustrated) in the device layer 813 or may be directly connected with the through-via 815. The second pad 833 may be disposed on the backside 801b of the chip substrate 811 and may be electrically connected with the through-via 815.

The first pads 831 and/or the second pads 833 may include metal, metal nitride, metal oxide, metal silicide, conductive carbon, or a combination thereof. For example, the first pads 831 and/or the second pads 833 may include Ag, Al, AlN, Au, Be, Bi, Co, Cu, Hf, In, Mn, Mo, Ni, Pb, Pd, Pt, Rh, Re, Ru, Sn, Ta, TaN, Te, Ti, TiN, W, WN, Zn, Zr, or a combination thereof. In some implementations, the first pads 831 and/or the second pads 833 may include one of Al, Cu, Ni, W, Pt, and Au.

Connectors 835 may connect two semiconductor chips 810 adjacent to each other. The connectors 835 may be provided between the first pads 831 and the second pads 833 that face each other between the two adjacent semiconductor chips 810 adjacent to each other. The connectors 835, which connect the two semiconductor chips 810 adjacent to each other, may be at least one of conductive bumps, conductive balls, conductive pins, conductive leads, conductive pillars, or a combination thereof. For example, each of the connectors 835 may include an under bump metal (UBM) and a conductive bump.

The first pads 831, the second pads 833, and the connectors 835 may constitute package substrates 900 that connect the two semiconductor chips 810 adjacent to each other. The package substrates 900 may be provided in the adhesive layers 820. The space between the two semiconductor chips 810, where the package substrates 900 are provided, may be filled with the adhesive layers 820.

The connectors 835 connected to the backside 801b of the lowermost semiconductor chip 810 may be used to electrically connect the semiconductor device 800 and external components (e.g., a base substrate, an interposer, and a package substrate 900 to be described below). The connectors 835 connected to the backside 801b of the lowermost semiconductor chip 810 may transfer at least one of a control signal, a power signal, or a ground signal for operation of the semiconductor chips 810 from the outside to integrated circuit chips, may receive a data signal to be stored in the semiconductor chips 810 from the outside, or may provide data stored in the semiconductor chips 810 to the outside.

The first pads 831 may not be provided on the device layer 813 of the uppermost semiconductor chip 810. Since the first pads 831 are not provided, the through-vias 815 connected to the first pads 831 may not be provided.

The adhesive layers 820 may serve to attach two adjacent semiconductor chips 810 to each other and may include a polymer material that is cured through heat and/or light. For example, the adhesive layers 820 may include a resin and a filler. In this implementation, the resin may be a thermosetting resin, and the filler may include fine particles such as silica. However, the present disclosure is not limited thereto. In this implementation, the adhesive layers 820 may be non-conductive films (NCFs). In addition, the adhesive layers 820 may be die attach films (DAFs).

The semiconductor device 800 may further include an encapsulant 850 that surrounds the upper side of the uppermost semiconductor chip 810, the lateral sides of the semiconductor chips 810, and the lateral sides of the adhesive layers 820. For example, the encapsulant 850 may include an epoxy mold compound (EMC).

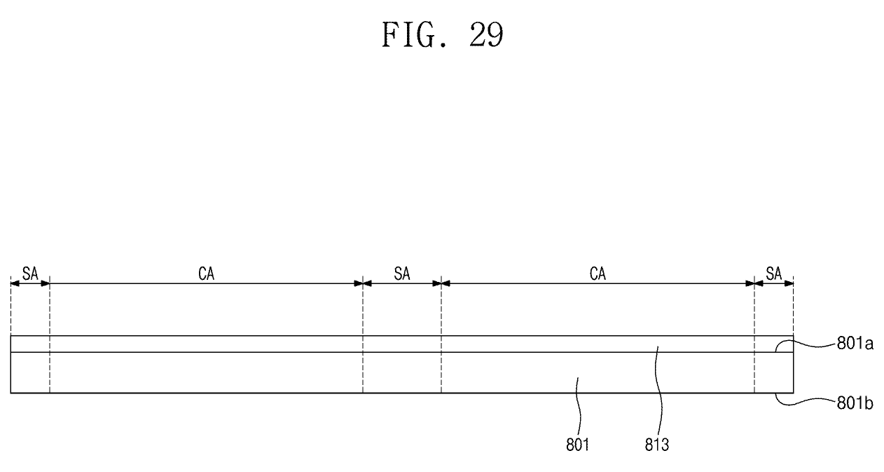

FIGS. 29 to 33 are sectional views illustrating a semiconductor device manufacturing method according to some implementations of the present disclosure.

Referring to FIG. 29, a base layer 801 for forming the semiconductor chips 810 may be prepared. The base layer 801 may include chip regions CA and scribe lane regions SA between the chip regions CA. The scribe lane regions SA may surround the chip regions CA when viewed from above a plane.

Each of the chip regions CA may include the device layer 813 including a plurality of integrated circuits and/or wires. The scribe lane regions SA may be disposed outside the chip regions CA in a shape surrounding the chip regions CA.

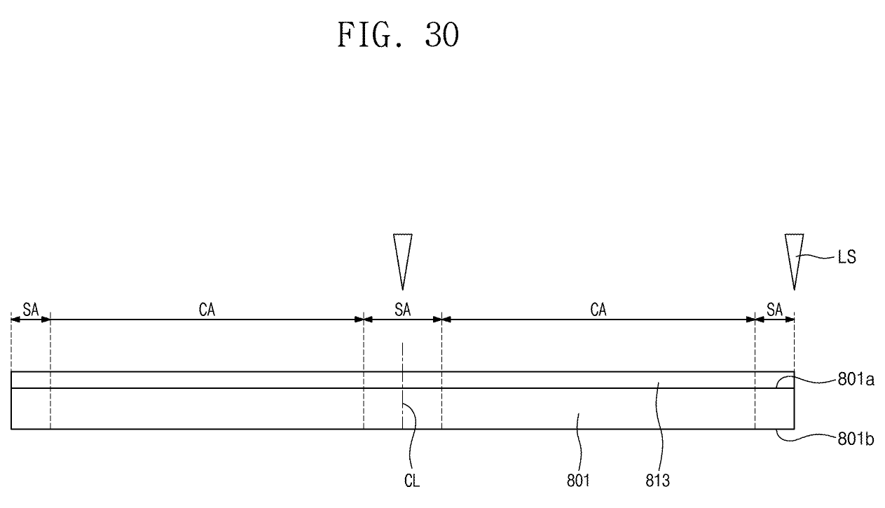

Referring to FIG. 30, the base layer 801 and the device layer 813 may be cut along cut lines CL defined on the scribe lane regions SA.

The cutting process of cutting the base layer 801 and the device layer 813 along the cut lines CL to divide the base layer 801 and the device layer 813 into the semiconductor chips 810 may be the laser cutting process according to the above-described implementations.

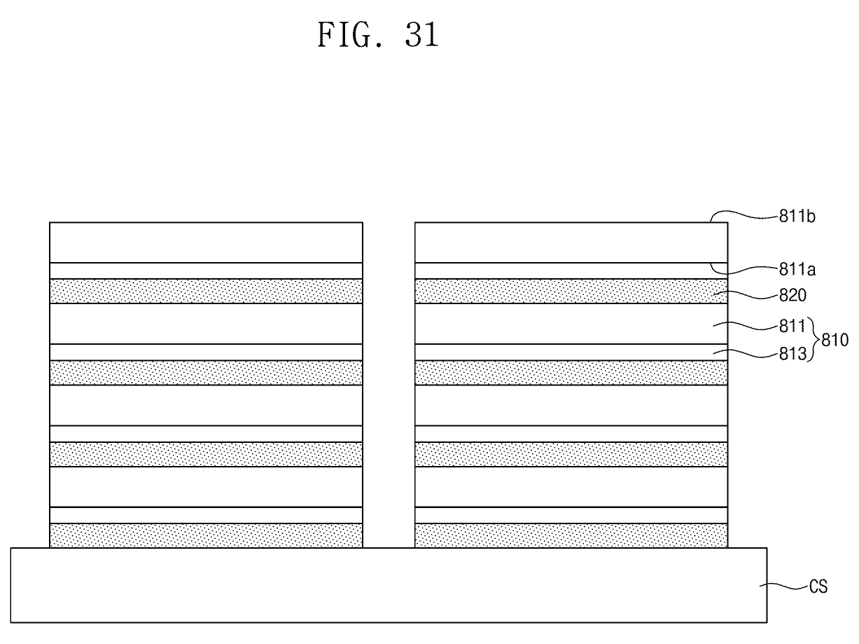

Referring to FIG. 31, a plurality of stacked semiconductor chips 810 may be disposed on a carrier substrate CS.

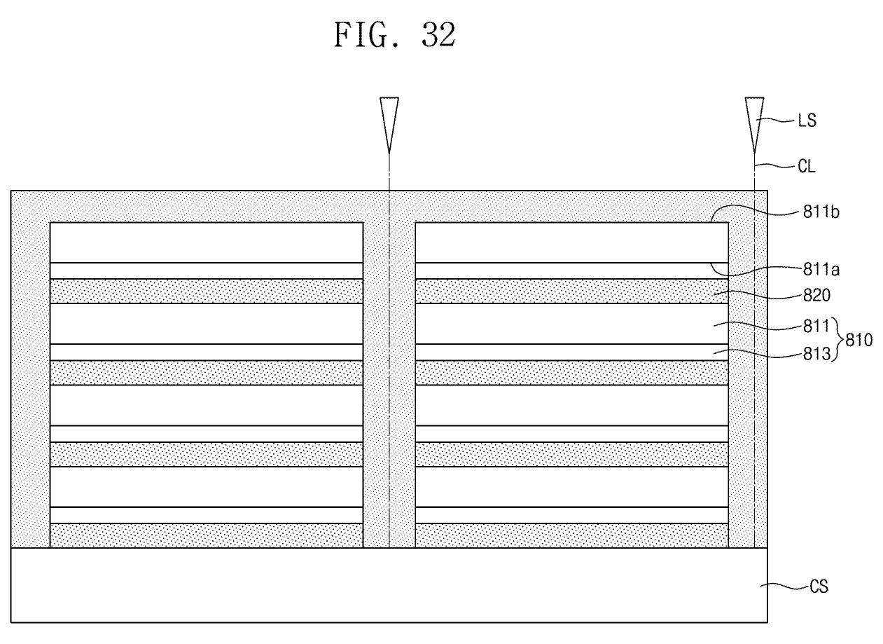

Referring to FIG. 32, the encapsulant 850 that covers the plurality of stacked semiconductor chips 810 may be formed on the carrier substrate CS. The encapsulant 850 may surround the upper side of the uppermost semiconductor chip 810, the lateral sides of the semiconductor chips 810, and the lateral sides of the adhesive layers 820. The encapsulant 850 may include various materials. For example, the encapsulant 850 may include an epoxy mold compound (EMC).

The semiconductor device having the encapsulant 850 formed therein may be cut along cut lines by a cutting apparatus and may be divided into the semiconductor devices 800. The cutting process of cutting the encapsulant 850 along the cut lines to divide the semiconductor device into the semiconductor devices 800 may be the laser cutting process according to the above-described method. In some implementations, the cutting process may be a process that performs cutting through grinding after emission of a laser.

Although not illustrated, before the semiconductor device having the encapsulant 850 formed therein is cut, the carrier substrate CS may be separated and removed from the semiconductor device having the encapsulant 850 formed therein.

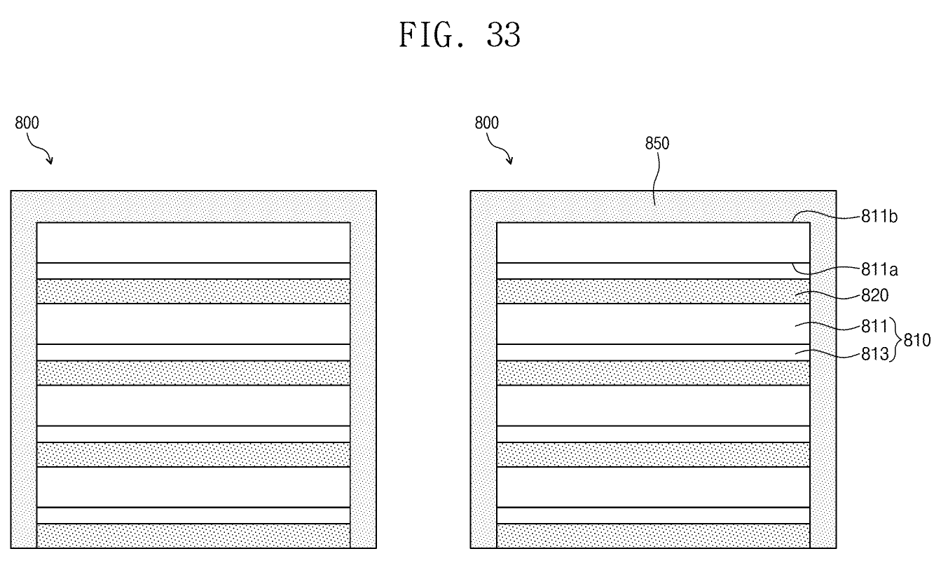

Referring to FIG. 33, the plurality of individual semiconductor devices 800 may be manufactured by cutting the semiconductor device having the encapsulant 850 formed therein.

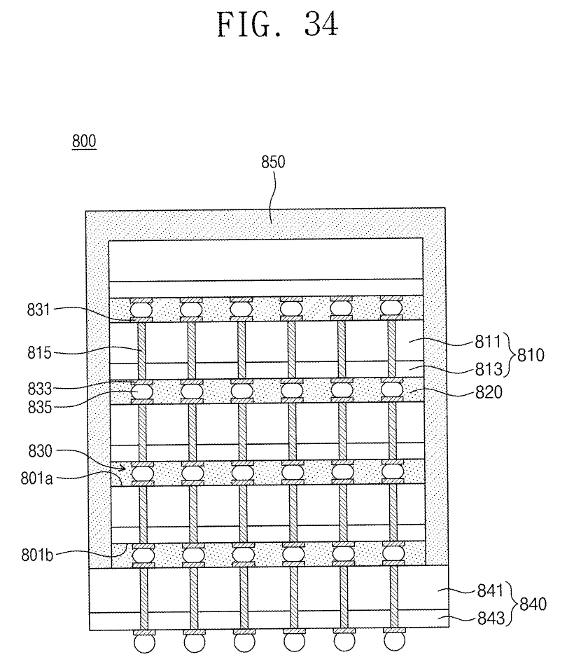

FIG. 34 is a sectional view illustrating the semiconductor device 800 manufactured by the semiconductor device manufacturing method according to some implementations of the present disclosure.

Referring to FIG. 34, the semiconductor device 800 according to some implementations of the present disclosure may include a base chip 840 and a plurality of semiconductor chips 810. For example, the plurality of semiconductor chips 810 may include four semiconductor chips 810. The base chip 840 and the plurality of semiconductor chips 810 may be sequentially stacked with the adhesive layers 820 therebetween.

The base chip 840 may include a base chip substrate 841 and a base circuit layer 843 provided on the base chip substrate 841. Each of the semiconductor chips 810 may include the chip substrate 811 and the device layer 813. The base chip 840 and the semiconductor chips 810 may further include the through-vias 815, the first pads 831, and the second pads 833.

The base chip 840 and the semiconductor chips 810 may each be a logic chip and/or a memory chip. For example, the base chip 840 and/or the semiconductor chips 810 may all be memory chips of the same type. Alternatively, some of the plurality of semiconductor chips 810 may be memory chips, and the others may be logic chips.

In some implementations of the present disclosure, the base chip 840 and the semiconductor chips 810 may be high bandwidth memory (HBM) DRAM. In this case, the base chip 840 may be a buffer chip or a control chip. The base chip 840 may integrate signals of a plurality of DRAM chips and may transfer the integrated signals to the outside. In addition, the base chip 840 may transfer signals and power from the outside to the plurality of DRAM chips. For example, in some implementations, the base chip 840 may correspond to a master chip. Each of the semiconductor chips 810 stacked on the base chip 840 may correspond to a slave chip.

The semiconductor device 800 may further include, on the base chip 840 and the semiconductor chips 810, the encapsulant 850 that surrounds the upper side of the uppermost semiconductor chip 810, the lateral sides of the semiconductor chips 810, and the lateral sides of the adhesive layers 820. The base chip 840, when viewed from above a plane, may have a larger area than the semiconductor chips 810. The encapsulant 850 may be provided on the base chip 840 and may not cover the lateral side of the base chip 840. The outer side of the encapsulant 850 may form the same plane as the outer side of the base chip 840.

The semiconductor device according to some implementations of the present disclosure manufactured by the above-described method may be applied to various semiconductor packages 10.

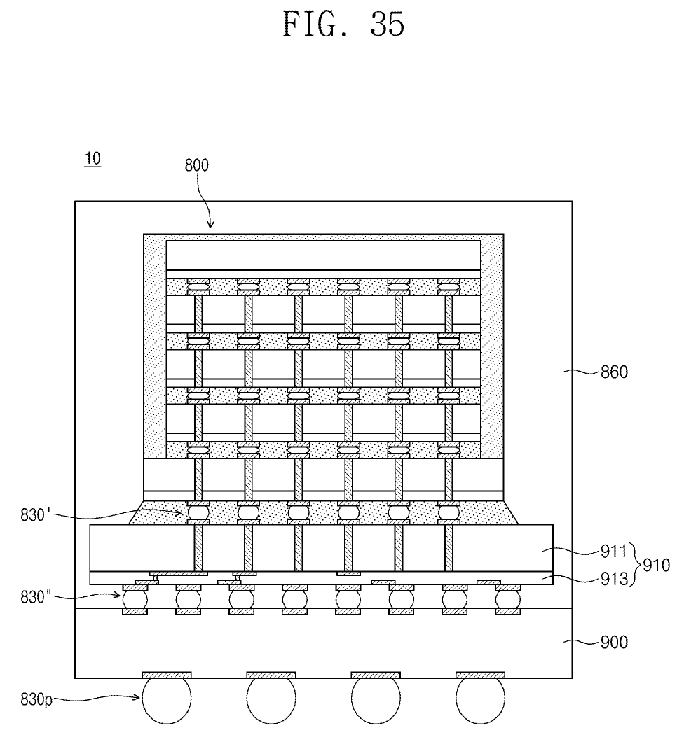

FIG. 35 is a view illustrating a semiconductor package 10 according to some implementations of the present disclosure.

Referring to FIG. 35, the semiconductor package 10 according to some implementations of the present disclosure may include a package substrate 900, a main semiconductor chip 910 mounted on the package substrate 900, and a semiconductor device 800 stacked on the main semiconductor chip 910.

The main semiconductor chip 910 may be a processor unit. For example, the main semiconductor chip 910 may be a microprocessor unit (MPU) or a graphics processor unit (GPU). The main semiconductor chip 910 may include a main chip substrate 911, a circuit layer 913, and main through-vias. The main through-vias have a structure similar to the structure of the through-vias 815 of the base chip 840 and the semiconductor chips 810, and therefore a detailed description thereof will be omitted.

Connecting terminals 130’ and 130” may be provided between the semiconductor device 800 and the main semiconductor chip 910 and between the main semiconductor chip 910 and the package substrate 900. The connecting terminals 130’ and 130” may include first pads 831 and second pads 833 facing each other and connectors 835 between the first pads 831 and the second pads 833. The connectors 835 may be at least one of conductive bumps, conductive balls, conductive pins, conductive leads, conductive pillars, or a combination thereof. For example, each of the connectors 835 may include a conductive pillar or a solder ball.

The upper side of the package substrate 900, the upper side and the lateral side of the semiconductor device 800, and the upper side and the lateral side of the main semiconductor chip 910 may be covered by an outer encapsulant 860.

An external connecting terminal 830p may be attached to the lower side of the package substrate 900. For example, the external connecting terminal 830p may be attached to a lower pad. For example, the external connecting terminal 830p may be a solder ball or a bump. The external connecting terminal 830p may electrically connect the semiconductor package 10 and an external device.

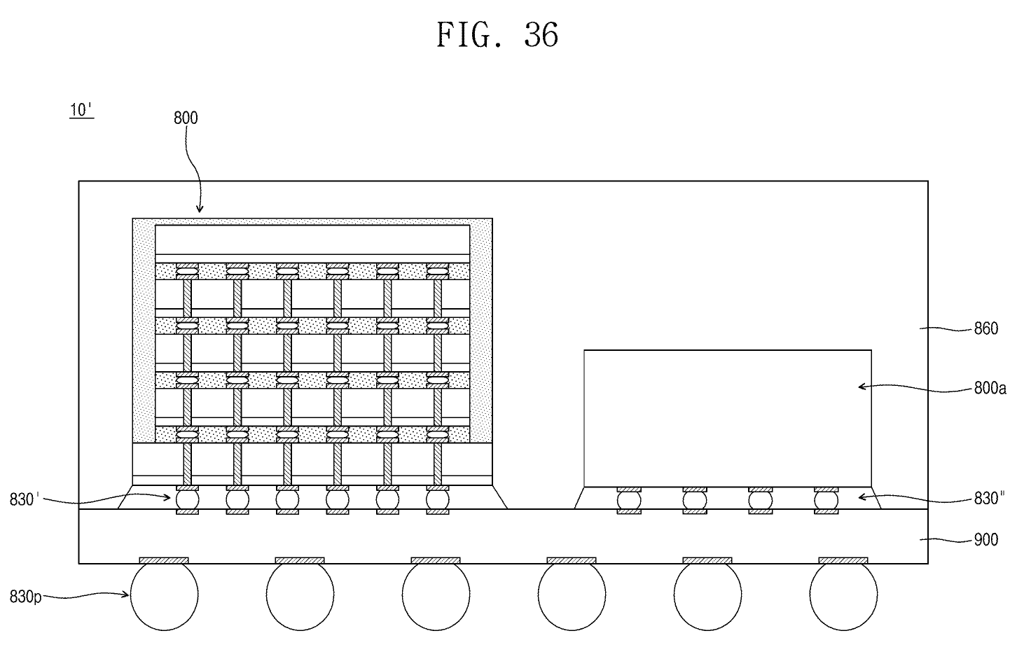

FIG. 36 is a view illustrating a semiconductor package 10’ according to some implementations of the present disclosure.

Referring to FIG. 36, the semiconductor package 10’ according to some implementations of the present disclosure may include a package substrate 900 and a first semiconductor device 800 and a second semiconductor device 800a that are mounted on the package substrate 900. The first semiconductor device 800 may be manufactured according to the above-described implementation.

The second semiconductor device 800a may be the same as, or different from, the first semiconductor device 800. In some implementations, the second semiconductor device 800a may include high bandwidth memory (HBM), hybrid memory cube (HMC), double data rate fifth-generation (DDR5) DRAM, or a combination thereof. Alternatively, the second semiconductor device 800a may include a microprocessor, a logic chip, an application processor, a graphics processing unit, a buffer chip, or a combination thereof.

The upper side of the package substrate 900, the upper side and the lateral side of the first semiconductor device 800, and the upper side and the lateral side of the second semiconductor device 800a may be covered by an outer encapsulant 860.

An external connecting terminal 830p may be attached to the lower side of the package substrate 900. For example, the external connecting terminal 830p may be attached to a lower pad. For example, the external connecting terminal 830p may be a solder ball or a bump. The external connecting terminal 830p may electrically connect the semiconductor package 10’ and an external device.

A semiconductor device according to some implementations of the present disclosure may be applied to the semiconductor packages 10 and 10’ described above. However, this is illustrative, and the semiconductor device may be applied to various other semiconductor devices and semiconductor packages.

According to some implementations of the present disclosure, the semiconductor device manufacturing method may improve reliability and stability.

Furthermore, according to some implementations of the present disclosure, the semiconductor device manufacturing method may simultaneously process the plurality of scribe lane regions, thereby efficiently cutting the wafer.

Moreover, according to some implementations of the present disclosure, the semiconductor device manufacturing method may individually control the beams emitted to the plurality of scribe lane regions, thereby improving reliability and stability.

In addition, according to implementations of the present disclosure, the semiconductor device manufacturing method may prevent the beam for forming the groove from leaking out of the wafer, thereby reducing scattering of the beam in the chamber and generation of byproducts.

According to some implementations, a laser cutting apparatus for cutting an object being processed along a scan direction includes a light source that generates a laser beam, a spatial separation optical system that spatially divides the laser beam into a first beam and a second beam, a time-delay optical system that makes an emission time point of the first beam later than an emission time point of the second beam, and an acousto-optic modulator that selectively changes an emission direction of the first beam or an emission direction of the second beam.

The spatial separation optical system may spatially divide the first beam and the second beam in a direction crossing the scan direction.

The spatial separation optical system may rotate in a planar view to adjust a gap between the first beam and the second beam in a direction perpendicular to the scan direction.

The acousto-optic modulator may periodically generate an induced diffraction grating, based on an RF signal having a period corresponding to a time delay generated by the time-delay optical system.

The laser cutting apparatus may further include a sub-separation optical system that spatially divides the first beam into first sub-beams in the scan direction and spatially divides the second beam into second sub-beams in the scan direction.

The sub-separation optical system may be provided between the acousto-optic modulator and the time-delay optical system, and the acousto-optic modulator may selectively change an emission direction of the first sub-beams or an emission direction of the second sub-beams.

The laser cutting apparatus may further include a light blocking device that absorbs the first sub-beams or the second sub-beams, the emission direction of which is changed by the acousto-optic modulator.

The laser cutting apparatus may further include a sub-separation optical system that spatially divides one of the first beam and the second beam passing through the acousto-optic modulator in the scan direction and a light blocking device that absorbs the other one of the first beam and the second beam diffracted by the acousto-optic modulator, and the acousto-optic modulator may be provided between the time-delay optical system and the sub-separation optical system.

The spatial separation optical system may include a birefringent material. The spatial separation optical system may divide the laser beam into the first beam and the second beam depending on a polarization direction.

The time-delay optical system may include a birefringent material. The time-delay optical system may provide different refractive indexes, based on a polarization direction of the first beam and a polarization direction of the second beam.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to implementations thereof, it will be apparent to those of ordinary skill in the art that various changes and modifications may be made thereto without departing from the spirit and scope of the present disclosure as set forth in the following claims.

What is claimed is:

1. A method for manufacturing a semiconductor device, the method comprising:
preparing a wafer having a plurality of chip regions and a plurality of scribe lane regions defining the plurality of chip regions, wherein the plurality of scribe lane regions include a first scribe lane region and a second scribe lane region that extend parallel to each other in a scan direction;
forming a plurality of grooves in at least one of a dual emission period or a single emission period;
attaching a dicing tape to a backside of the wafer; and
cutting the wafer into a plurality of semiconductor devices,
wherein forming the plurality of grooves include:
during the single emission period, forming a first groove of the plurality of grooves by emitting a first beam to the first scribe lane region along the scan direction, and forming a second groove of the plurality of grooves by independently emitting a second beam to the second scribe lane region along the scan direction, or
during the dual emission period, forming the first groove and forming the second groove by simultaneously emitting the first beam and the second beam to the first scribe lane region and the second scribe lane region along the scan direction, respectively.

2. The method of claim 1, wherein emitting the first beam starts before emitting the second beam.

3. The method of claim 1, wherein emitting the first beam ends after emitting the second beam.

4. The method of claim 1, wherein the second scribe lane region has a length in the scan direction greater than a length of the first scribe lane region in the scan direction, and
wherein emitting the second beam starts before emitting the first beam and ends after emitting the first beam.

5. The method of claim 1, wherein the plurality of scribe lane regions include an odd number of scribe lane regions,
wherein the odd number of scribe lane regions include at least one pair of scribe lane regions and one remaining scribe lane region, and
wherein the method comprises:
emitting the first beam and the second beam to the at least one pair of scribe lane regions; and
emitting either the first beam or the second beam to the one remaining scribe lane region.

6. The method of claim 1, comprising:
spatially dividing a laser beam into the first beam and the second beam in a direction crossing the scan direction before emitting the first beam and emitting the second beam.

7. The method of claim 6, comprising:
providing the first beam and the second beam to a time-delay optical system before emitting the first beam and emitting the second beam; and
providing the first beam and the second beam passing through the time-delay optical system to an acousto-optic modulator,
wherein the time-delay optical system is configured to cause an emission time point of one of the first beam and the second beam to be later than an emission time point of the other one of the first beam and the second beam, and
wherein the acousto-optic modulator is configured to change an emission direction of the first beam or an emission direction of the second beam based on a time difference between an emission time point of the first beam and an emission time point of the second beam during the single emission period.

8. The method of claim 7, wherein the acousto-optic modulator is configured to change the emission direction of the first beam during the single emission period such that the first beam departs from the wafer, and
wherein the second beam is emitted onto the wafer during the single emission period.

9. The method of claim 8, comprising:
absorbing the first beam using a light blocking device.

10. The method of claim 1, wherein the first beam includes first sub-beams spatially separate from each other in the scan direction,
wherein the second beam includes second sub-beams spatially separate from each other in the scan direction,
wherein the first sub-beams are configured to be emitted to the first scribe lane region, and
wherein the second sub-beams are configured to be emitted to the second scribe lane region.

11. The method of claim 1, wherein attaching the dicing tape is performed after emitting the first beam and emitting the second beam.

12. The method of claim 1, wherein attaching the dicing tape is performed before emitting the first beam and emitting the second beam.

13. The method of claim 11, comprising:
polishing the backside of the wafer between preparing the wafer and attaching the dicing tape,
wherein the dicing tape is attached to the polished backside of the wafer.

14. The method of claim 1, comprising dividing a laser beam into the first beam and the second beam using a spatial separation optical system,
wherein a distance between the first beam and the second beam in a direction perpendicular to the scan direction in a planar view is defined as a separation distance, and
wherein the method comprises performing control such that the separation distance between the first beam and the second beam corresponds to a distance between the first scribe lane region and the second scribe lane region, by rotating the spatial separation optical system in the planar view before emitting the first beam and emitting the second beam.

15. A method for manufacturing a semiconductor device, the method comprising:
preparing a wafer having a plurality of chip regions and a plurality of scribe lane regions configured to define the plurality of chip regions, wherein the plurality of scribe lane regions include a first scribe lane region and a second scribe lane region configured to extend parallel to each other in a scan direction, and the second scribe lane region includes a first portion configured to face the first scribe lane region and a second portion configured not to face the first scribe lane region;
dividing a laser beam into a first beam and a second beam;
forming a first groove by emitting the first beam to the first scribe lane region along the scan direction;
forming a second groove by emitting the second beam to the second scribe lane region along the scan direction, the first beam being blocked while emitting the second beam to the second portion of the second scribe lane region;
attaching a dicing tape to a backside of the wafer; and
forming a plurality of semiconductor chips separate from each other by cutting the wafer.

16. The method of claim 15, wherein emitting the second beam to the second scribe lane region comprises emitting the second beam to the first portion of the second scribe lane region while emitting the first beam to the first scribe lane region.

17. The method of claim 16, wherein emitting the first beam to the first scribe lane region and emitting the second beam to the first portion of the second scribe lane region start at the same time.

18. The method of claim 16, wherein emitting the first beam to the first scribe lane region and emitting the second beam to the first portion of the second scribe lane region end at the same time.

19. A method for manufacturing a semiconductor device, the method comprising:
preparing a wafer having a plurality of chip regions and a plurality of scribe lane regions configured to define the plurality of chip regions, wherein the plurality of scribe lane regions include a first scribe lane region and a second scribe lane region configured to extend parallel to each other in a scan direction;
dividing, by a spatial separation optical system, a laser beam into a first beam and a second beam;
forming a first groove by emitting the first beam to the first scribe lane region along the scan direction;
forming a second groove by emitting the second beam to the second scribe lane region along the scan direction;
attaching a dicing tape to a backside of the wafer; and
cutting the wafer into a plurality of semiconductor devices,
wherein the method comprises controlling a separation distance to correspond to a distance between the first scribe lane region and the second scribe lane region, by rotating the spatial separation optical system in a planar view before emitting the first beam and emitting the second beam, wherein the separation distance is defined between the first beam and the second beam in a direction perpendicular to the scan direction in the planar view.

20. The method of claim 19, wherein the second scribe lane region has a length in the scan direction greater than a length of the first scribe lane region in the scan direction,
wherein emitting the first beam starts before emitting the second beam.
